(19) United States
(12) Patent Application Publication
(10) Pub. No.: US 2025/0218503 A1
(43) Pub. Date: Jul. 3, 2025

(54) SEMICONDUCTOR DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Takanori MATSUZAKI, Atsugi (JP); Hajime KIMURA, Atsugi (JP); Hidetomo KOBAYASHI, Isehara (JP); Hiroki INOUE, Atsugi (JP); Yuki OKAMOTO, Ebina (JP)

(21) Appl. No.: 18/881,494

(22) PCT Filed: Jul. 20, 2023
(86) PCT No.: PCT/IB2023/057377

§ 371 Date: Jan. 6, 2025

(30) Foreign Application Priority Data
Aug. 2, 2022 (JP) 2022-123244
Sep. 22, 2022 (JP) 2022-151115

(51) Int. Cl. G11C 11/4096; G11C 5/06; G11C 11/4091

(52) U.S. Cl. CPC G11C 11/4096; G11C 5/06; G11C 11/4091

(57) ABSTRACT

A semiconductor device with a novel structure is provided. The semiconductor device includes an arithmetic device, a bus wiring, and a memory device. The memory device includes a first element layer including a plurality of reading circuits and a second element layer including a plurality of cell arrays. The reading circuits each include a sense amplifier. The cell arrays each include a memory cell. The second element layer is provided to be over and overlap with the first element layer. The memory cell and the sense amplifier are electrically connected to each other through a bit line. The memory device is electrically connected to the arithmetic device through a bus wiring. Data retained in one of the plurality of cell arrays is output to the bus wiring through one of the plurality of reading circuits. The data output to the bus wiring is output with a bit width that is a multiple of 8 bits.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a storage device (memory device), a driving method thereof, and a manufacturing method thereof.

### BACKGROUND ART

A DRAM (Dynamic Random Access Memory) stores data by accumulation of charge in a capacitor. Thus, a lower off-state current of an access transistor for controlling the supply of charge to the capacitor is preferable, because the lower off-state current enables a longer data retention period and a lower frequency of refresh operation.

A transistor including a metal oxide semiconductor (preferably an oxide semiconductor containing In, Ga, and Zn) in its semiconductor layer is known as a kind of transistor. It is known that a transistor including a metal oxide in its semiconductor layer has an extremely low off-state current. Note that in this specification, a transistor including a metal oxide in its semiconductor layer is referred to as an oxide semiconductor transistor, a metal oxide transistor, an OS transistor, or the like in some cases.

The use of an OS transistor enables a semiconductor device having excellent data retention characteristics to be formed. For example, Patent Document 1 describes that a semiconductor device can be downsized by stacking a peripheral circuit and a cell array.

### REFERENCE

### Patent Document

[Patent Document 1] Japanese Published Patent Application No. 2012-256821

### SUMMARY OF THE INVENTION

### Problems to be Solved by the Invention

To achieve higher performance and lower power consumption of a computing system, a further reduction in power consumption, an increase in operating speed, downsizing, an increase in memory capacity, and the like, in a semiconductor device such as a DRAM are required.

An object of one embodiment of the present invention is to provide a semiconductor device with a novel structure. Another object of one embodiment of the present invention is to provide a semiconductor device that is excellent in reducing power consumption, increasing operation speed, downsizing, or increasing memory capacity.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects.

### Means for Solving the Problems

One embodiment of the present invention is a semiconductor device including an arithmetic device, a bus wiring, and a memory device; the memory device includes a first element layer including a plurality of reading circuits and a second element layer including a plurality of cell arrays; the reading circuits each include a sense amplifier; the cell arrays each include a memory cell; the second element layer is provided to be over and overlap with the first element layer; the memory cell and the sense amplifier are electrically connected to each other through a bit line; the memory device is electrically connected to the arithmetic device through the bus wiring; and data retained in one of the plurality of cell arrays is output to the bus wiring through one of the plurality of reading circuits.

In the semiconductor device of one embodiment of the present invention, it is preferable that the data output to the bus wiring be output with a bit width that is a multiple of 8 bits.

In the semiconductor device of one embodiment of the present invention, it is preferable that the first element layer include an input/output circuit and the input/output circuit include a plurality of interface circuits.

In the semiconductor device of one embodiment of the present invention, it is preferable that the reading circuits each include a precharge circuit.

In the semiconductor device of one embodiment of the present invention, it is preferable that the first element layer include a first transistor in which a first semiconductor layer including a channel formation region includes silicon and the second element layer include a second transistor in which a second semiconductor layer including a channel formation region includes an oxide semiconductor.

In the semiconductor device of one embodiment of the present invention, the oxide semiconductor preferably includes In, Ga, and Zn.

In the semiconductor device of one embodiment of the present invention, the memory cell includes a capacitor and the second transistor; the capacitor includes a first conductor, a second conductor, a first insulator, and a second insulator; the second transistor includes the second conductor, a third conductor, a fourth conductor, a third insulator, a fourth insulator, and the second semiconductor layer; the first insulator includes a first opening; the first conductor is positioned on a side surface and a bottom surface of the first opening and a top surface of the first insulator; the second insulator is positioned on the top surface of the first insulator and a top surface and a side surface of the first conductor; the second conductor is positioned in a region of a top surface and a side surface of the second insulator that overlaps with the first conductor; the third insulator is positioned on a top surface of the second conductor; the third conductor is positioned on a top surface of the third insulator; the third insulator and the third conductor include a second opening; the second semiconductor layer is positioned on a side surface of the second opening, the top surface of the second conductor, and a top surface and a side surface of the third conductor; the fourth insulator is positioned on a top surface and a side surface of the second semiconductor layer and the top surface of the third conductor; and the fourth conductor is positioned in a region of a top surface and a side surface of the fourth insulator that overlaps with the second semiconductor layer.

Note that other embodiments of the present invention will be described in the following embodiments and the drawings.

### Effect of the Invention

One embodiment of the present invention can provide a novel semiconductor device or the like. Another embodiment of the present invention can provide a semiconductor device that is excellent in reducing power consumption, increasing operation speed, downsizing, or increasing memory capacity.

Note that the description of these effects does not preclude the existence of other effects. Note that one embodiment of the present invention does not necessarily need to have all these effects. Note that other effects will be apparent from the description of the specification, the drawings, the claims, and the like and other effects can be derived from the description of the specification, the drawings, the claims, and the like.

### BRIEF DESCRIPTION OF THE DRAWINGS

FIG. 1A is a block diagram illustrating a structure example of a semiconductor device. FIG. 1B is a perspective view illustrating the structure example of the semiconductor device.

FIG. 2A is a block diagram illustrating a structure example of a semiconductor device. FIG. 2B is a timing chart illustrating the structure example of the semiconductor device.

FIG. 3A is a block diagram illustrating a structure example of a semiconductor device. FIG. 3B is a timing chart illustrating the structure example of the semiconductor device.

FIG. 4A is a block diagram illustrating a structure example of a semiconductor device. FIG. 4B is a perspective view illustrating the structure example of the semiconductor device.

FIG. 5A is a block diagram illustrating a structure example of a semiconductor device. FIG. 5B and FIG. 5C are circuit diagrams each illustrating the structure example of the semiconductor device.

FIG. 6 is a circuit diagram illustrating a structure example of a semiconductor device.

FIG. 7A and FIG. 7B are schematic views each illustrating a structure example of a semiconductor device.

FIG. 8A and FIG. 8B are schematic views each illustrating a structure example of a semiconductor device.

FIG. 9 is a block diagram illustrating a structure example of a semiconductor device.

FIG. 10A to FIG. 10E are circuit diagrams each illustrating a structure example of a semiconductor device.

FIG. 11A and FIG. 11B are schematic views each illustrating a structure example of a semiconductor device.

FIG. 12 is a cross-sectional view illustrating a structure example of a semiconductor device.

FIG. 13 is a cross-sectional view illustrating a structure example of a semiconductor device.

FIG. 14A to FIG. 14C are cross-sectional views each illustrating a structure example of a semiconductor device.

FIG. 15 is a cross-sectional view illustrating a structure example of a semiconductor device.

FIG. 16 is a cross-sectional view illustrating a structure example of a memory device.

FIG. 17A is a diagram illustrating a structure example of a memory device. FIG. 17B is a diagram illustrating an equivalent circuit in the memory device.

FIG. 18 is a diagram illustrating a structure example of a memory device.

FIG. 19A is a diagram illustrating a structure example of a memory device. FIG. 19B is a diagram illustrating an equivalent circuit in the memory device.

FIG. 20 is a schematic cross-sectional view illustrating a structure example of a semiconductor device.

FIG. 21A to FIG. 21C are plan views each illustrating a structure example of a transistor included in a semiconductor device, and FIG. 21D is a cross-sectional view illustrating a structure example of a transistor included in the semiconductor device.

FIG. 22A is a plan view illustrating a structure example of a transistor included in a semiconductor device, and FIG. 22B is a cross-sectional view illustrating a structure example of a transistor included in a semiconductor device.

FIG. 23A to FIG. 23B are diagrams each illustrating an example of an electronic component.

FIG. 24A and FIG. 24B are diagrams each illustrating an example of an electronic device, and FIG. 24C to FIG. 24E are diagrams each illustrating an example of a large computer.

FIG. 25 is a diagram illustrating an example of space equipment.

FIG. 26 is a diagram illustrating an example of a storage system applicable to a data center.

### MODE FOR CARRYING OUT THE INVENTION

Embodiments will be described below with reference to the drawings. The embodiments can be implemented with various modes. It will be readily appreciated by those skilled in the art that modes and details can be changed in various ways without departing from the spirit and scope of the present invention. Therefore, the present invention should not be construed as being limited to the description of embodiments below.

In the drawings, the size, the layer thickness, or the region is sometimes exaggerated for clarity. Therefore, the size, the layer thickness, or the region is not limited to the illustrated scale. Note that the drawings schematically show ideal examples, and the embodiment of the present invention is not limited to shapes or values shown in the drawings.

Unless otherwise specified, an off-state current in this specification and the like refers to a drain current of a transistor in an off state (also referred to as a non-conducting state or a cutoff state). Unless otherwise specified, an off state refers to, in an n-channel transistor, a state where a voltage V_{gs} between its gate and source is lower than a threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as OS), and the like. For example, a metal oxide used in an active layer of a transistor is referred to as an oxide semiconductor in some cases. That is, an OS transistor can also be referred to as a transistor including a metal oxide or an oxide semiconductor.

### Embodiment 1

A semiconductor device described in one embodiment of the present invention functions as an SoC (System on Chip) in which the arithmetic device, the memory device, or the like inputs and outputs data through the bus wiring.

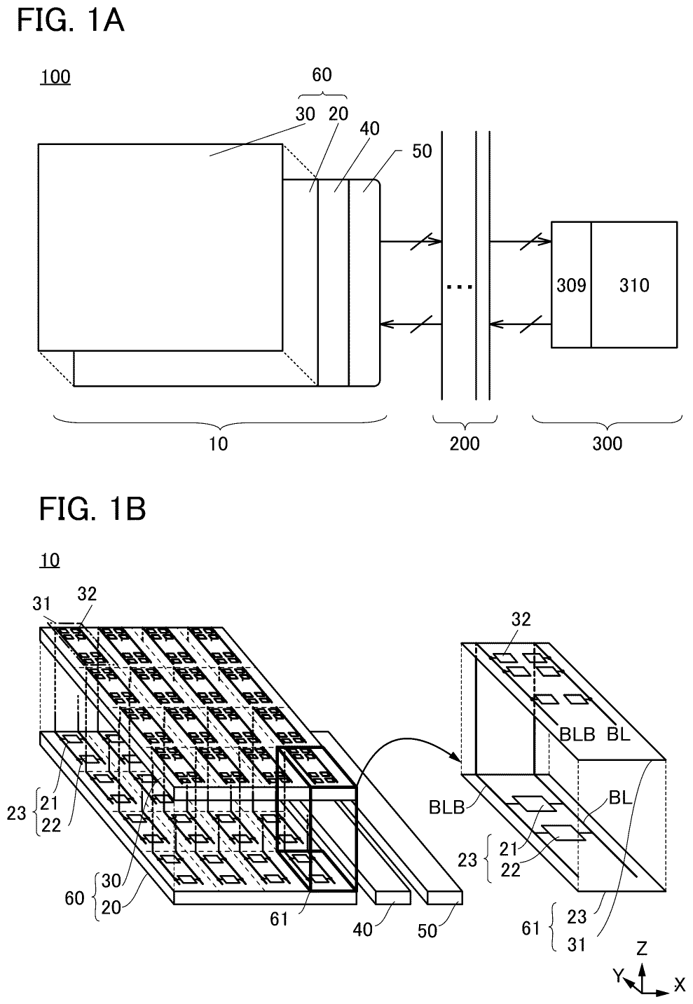

FIG. 1A is a block diagram schematically illustrating a semiconductor device 100 for describing one embodiment of the present invention. The semiconductor device 100 includes a memory device 10, a bus wiring 200, and an arithmetic device 300. FIG. 1B is a schematic view for describing a structure of the memory device 10.

Note that in this specification, the drawings, and the like, an X direction, a Y direction, and a Z direction are sometimes defined to describe arrangement of components. For example, in the schematic view illustrated in FIG. 1B, the X direction, the Y direction, and the Z direction are defined to describe arrangement of components included in the memory device 10. The X direction, the Y direction, and the Z direction are perpendicular or substantially perpendicular to each other.

In the schematic view illustrated in FIG. 1B, for easy understanding of the arrangement of the components included in the memory device 10, the components are separately illustrated. Components provided in the same layer are preferably formed in the same step; however, one embodiment of the present invention is not limited thereto. For example, a structure may be employed in which components formed in different steps are integrated with a bonding technique or the like.

The memory device 10 includes an element layer 20 and an element layer 30. In the memory device 10, the element layer 30 is stacked over the element layer 20. The element layer and the element layer 30 are layers including elements such as transistors. When elements such as transistors are included, the memory device 10 enables the element layers to be provided with circuits with different functions.

The element layer 20 includes a transistor in which a semiconductor layer including a channel formation region includes silicon (a Si transistor). The element layer 20 is an element layer provided with a substrate containing silicon. The element layer 20 is referred to as a base die or a die in some cases.

It is preferable for the Si transistors to use silicon with high crystallinity such as single crystal silicon or polycrystalline silicon in order to achieve high field-effect mobility and perform a higher-speed operation.

The element layer 30 includes a transistor in which a semiconductor layer including a channel formation region includes oxide semiconductor (an OS transistor). The element layer 30 including the OS transistor can be stacked over the element layer 20 including the Si transistor. The element layer 30 is referred to as a die in some cases. In the memory device 10 illustrated in FIG. 1A and FIG. 1B, a state where the element layer 30 is stacked over the element layer 20 is illustrated. When the element layer 30 is provided over the element layer 20, the transistor density per unit area can be increased.

Examples of a metal oxide used in the OS transistors include indium oxide, gallium oxide, and zinc oxide. The metal oxide preferably contains two or three selected from indium, an element M, and zinc. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide. Alternatively, it is preferable to use an oxide containing indium, tin, and zinc (also referred to as ITZO). Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO). Further alternatively, it is preferable to use an oxide containing indium (In), gallium (Ga), zinc (Zn), and tin (Sn) (also referred to as IGZTO).

The metal oxide used in the OS transistors may include two or more metal oxide layers with different compositions. For example, a stacked-layer structure of a first metal oxide layer having In: M:Zn=1:3:4 [atomic ratio] or a composition in the neighborhood thereof and a second metal oxide layer having In: M:Zn=1:1:1 [atomic ratio] or a composition in the neighborhood thereof and being formed over the first metal oxide layer can be suitably employed.

Alternatively, a stacked structure of one selected from indium oxide, indium gallium oxide, and IGZO, and one selected from IAZO, IAGZO, and ITZO may be employed, for example.

The metal oxide used in the OS transistors preferably has crystallinity. Examples of an oxide semiconductor having crystallinity include a CAAC (c-axis aligned crystalline)-OS and an nc (nanocrystalline)-OS. When the oxide semiconductor having crystallinity is used, the semiconductor device can have high reliability.

In the memory device 10, the element layer 20 and the element layer 30, or the circuits provided in the element layer 20 and the element layer 30 are collectively referred to as a memory block array 60. The memory block array 60 includes a plurality of memory blocks 61. The memory block 61 includes a cell array 31 including a plurality of memory cells 32 and a reading circuit 23 for reading data retained in the memory cells 32. The memory block 61 is composed of one set of the cell array 31 and the reading circuit 23.

The memory block 61 has a structure in which the cell array 31 and the reading circuit 23 are provided to overlap with each other. Note that in the case where the cell array 31 is referred to as a local cell array, the whole cell array composed of a plurality of cell arrays 31 is referred to as a memory cell array in some cases.

For example, the memory cell 32 is preferably a DOSRAM, which is a memory circuit including an OS transistor (also referred to as an OS memory). A DOSRAM (registered trademark) is an abbreviation for a “Dynamic Oxide Semiconductor Random Access Memory”. A DOSRAM refers to a RAM including a IT (transistor) 1C (capacitor) memory cell. A DOSRAM is a DRAM formed using an OS transistor, and a memory that temporarily stores information sent from the outside. A DOSRAM is a memory utilizing a low off-state current of an OS transistor.

In an OS transistor, a current that flows between a source and a drain in an off state, that is, an off-state current is extremely low. A DOSRAM can retain charge corresponding to data stored in a capacitor (also referred to as cell capacitance) for a long time by making an access transistor in an off state (by bringing the access transistor into a non-conducting state). For this reason, the refresh operation frequency of a DOSRAM can be lower than that of a DRAM formed using a Si transistor. As a result, power consumption can be reduced. Furthermore, a DOSRAM can be a memory cell that stores 1 bit data in a smaller occupation area than an SRAM formed using a Si transistor.

In addition, the memory cell 32 including an OS transistor can have a structure in which the cell array 31 is provided to overlap with the reading circuit 23; thus, the distance between the cell array 31 and the reading circuit 23 can be shortened. Therefore, power consumption needed for charge and discharge between wirings can be inhibited. When the cell array 31 is provided in each region that is to be the memory block 61, the number of the memory cells 32, which are electrically connected to the bit line, can be reduced. Thus, as well as the distance between the cell array 31 and the reading circuit 23, the number of memory cells 32 can be reduced, and the capacitance caused by the bit line (also referred to as bit line capacitance or load capacitance) can be reduced. By reducing the bit line capacitance, the capacitance included in the memory cell 32 can be designed to be small.

Although a DOSRAM is described as an example of the structure that can be used for the memory cell 32 in this embodiment, another structure may be employed as long as a cell array that can be stacked over the element layer 20 can be formed. For example, a NOSRAM that is a memory circuit including OS transistors may be used as well. NOSRAM (registered trademark) is an abbreviation for “Nonvolatile Oxide Semiconductor Random Access Memory (RAM)”. A memory cell in a NOSRAM is a two-transistor (2-T) or three-transistor (3T) gain cell.

Note that the transistors included in the memory cells 32 are all preferably OS transistors. In an OS transistor, a current that flows between a source and a drain in an off state, that is, an off-state current is extremely low. A NOSRAM can be used as a nonvolatile memory by retaining charge corresponding to data in the memory cell 32, using characteristics of extremely low off-state current. In particular, a NOSRAM is capable of reading retained data without destruction (non-destructive reading), and thus is suitable for arithmetic processing in which only a data reading operation is repeated many times.

The reading circuit 23 includes a precharge circuit 21 and a sense amplifier 22. The cell array 31 and the reading circuit 23 are electrically connected to each other with a bit line pair composed of a bit line BL and an inverted bit line BLB. The bit line BL and the inverted bit line BLB are simply referred to as wirings in some cases. Note that the bit line pair is a combination of the bit line and the inverted bit line that are compared simultaneously by the sense amplifier 22, and is sometimes referred to as a bit line pair (BL, BLB). Note that the sense amplifier 22 indicates a local sense amplifier in some cases. In this case, the whole sense amplifier composed of a plurality of sense amplifiers 22 is referred to as a sense amplifier array in some cases.

The reading circuit 23 is electrically connected to one bit line pair. The reading circuit 23 has a function of equilibration (an equalizer) in addition to a function of precharging a bit line pair.

The sense amplifier 22 is electrically connected to one bit line pair. The sense amplifier 22 has a function of amplifying the potential difference between the bit line pair (BL, BLB). In FIG. 1B, the bit line pair (BL, BLB) for connecting the sense amplifier 22 and the memory cell 32 included in the memory block 61 is led to both the cell array 31 and the reading circuit 23. In this case, a structure can be employed in which electrical connection is made through via which is formed using a conductor provided between the sense amplifier 22 and the memory cell 32, without leading a bit line pair between adjacent cell arrays. That is, the bit line in the reading circuit 23 is electrically connected to the bit line pair (BL, BLB) in the cell array 31. The memory device 10 includes a control circuit 40 and an input/output circuit 50. Although not illustrated, the memory device 10 includes a driver circuit such as a decoder for driving the cell array 31 and the reading circuit 23.

The input/output circuit 50 has a function of delivering signals from/to an external device such as the bus wiring 200. The input/output circuit 50 includes a plurality of interface circuits. As an interface circuit, I2C, LVDS (Low-Voltage Differential Signaling), MIPI (Mobile Industry Processor Interface), SPI (Serial Peripheral Interface), or the like is given. The input/output circuit 50 has a function of delivering signals between an external device such as the bus wiring 200 and the memory device 10 through the interface circuit.

The control circuit 40 has a function of processing a setting parameter and a command signal from the outside and determining the operating mode of the memory device 10. The control circuit 40 has a function of generating a variety of control signals and controlling the operation of the whole memory device 10. Note that the control circuit 40 and the input/output circuit 50 included in the memory device 10 can be formed using the transistors and wirings included in the element layer 20 or the element layer 30.

The arithmetic device 300 includes an arithmetic portion 310 and an input/output circuit 309. The arithmetic device 300 has a function of performing general-purpose processing such as execution of an operating system, control of data, various kinds of arithmetic operations and an execution of programs, like a CPU (Central Processing Unit) or a GPU (Graphics Processing Unit). Like the input/output circuit 50, the input/output circuit 309 includes an interface circuit and has a function of delivering signals from/to an external device such as the bus wiring 200 through the interface circuit. The arithmetic portion 310 has a function of performing an arithmetic operation on the basis of input data. The arithmetic portion 310 is referred to as a CPU core in some cases.

The plurality of memory blocks 61 included in the memory device 10 described with reference to FIG. 1A and FIG. 1B each include the cell array 31 and the reading circuit 23. Thus, by operating the plurality of memory blocks 61 at the same time, data retained in the memory cells 32 of the plurality of cell arrays 31 can be read by the corresponding reading circuits 23. That is, in the memory device 10, data retained in each memory cell 32 can be read to the bus wiring 200 in accordance with the number of the memory blocks 61 in parallel. For example, in the case where 8-bit data is read from the cell array 31 included in one memory block 61, a structure can be employed where data with the 64-bit bit width is read by reading data from the eight memory blocks in parallel.

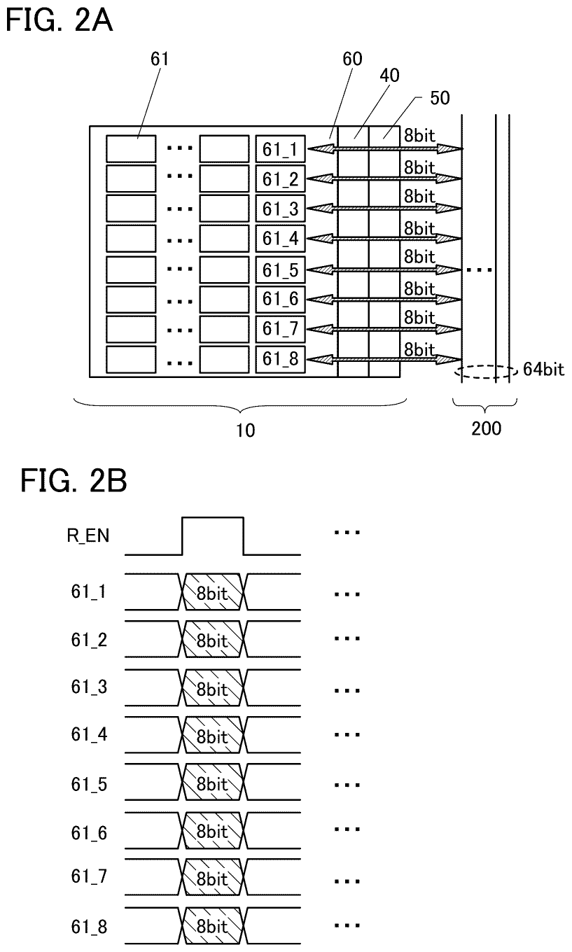

In a schematic view illustrated in FIG. 2A, a state of the memory blocks 61 (61_1 to 61_8) included in the memory device 10 where 8-bit data is output to the bus wiring 200 having the 64-bit bit width is illustrated.

8-bit data is read in parallel from the plurality of memory blocks 61. For example, as illustrated in FIG. 2B, 8-bit data is read in parallel from the memory blocks 61_1 to 61_8 in accordance with a read signal R_EN, whereby the data can be output to the bus wiring 200 including data with the 64-bit bit width. Thus, even when the speed of reading data from the memory cell 32 is lower than the speed of data reading operation of an interface through the input/output circuit 50, a bit width of read data can be increased by increasing the number of the memory blocks 61 in parallel.

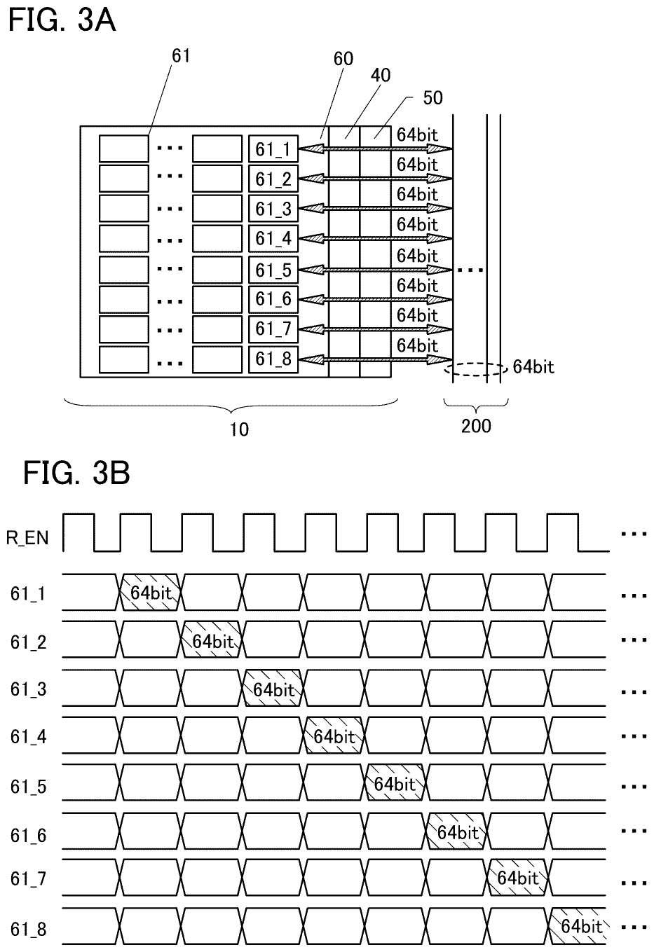

A structure different from that in FIG. 2A and FIG. 2B is described with reference to schematic views illustrated in FIG. 3A and FIG. 3B.

In a schematic view illustrated in FIG. 3A, a state of the memory blocks 61 (61_1 to 61_8) included in the memory device 10 where 64-bit data is output to the bus wiring 200 having the 64-bit bit width is illustrated.

Data with a bit width of more than 64 bits cannot be output at a time to the bus wiring 200 having the 64-bit bit width at a time. Therefore, a structure in which reading from the plurality of memory blocks 61 is sequentially performed from the plurality of memory blocks 61 is preferably employed. For example, as illustrated in FIG. 3B, 64-bit data can be sequentially read from the memory blocks 61_1 to 61_8 sequentially in accordance with the read signal R_EN, and data appropriate to the bus wiring 200 having the 64-bit bit width can be output. Also, the number of memory blocks 61 connected to the bus wiring 200 can be reduced, so that the parasitic capacitance of the bus wiring 200 can be reduced.

A bit width of data output from the plurality of memory blocks 61 is preferably variable in accordance with the bit width of the bus wiring 200. For example, one memory block 61 employs a structure in which data with a bit width that is a multiple of 8 bits (a multiple of 1 byte) is output, and a bit width of data output is variable in accordance with the number of memory blocks 61 in parallel. In this case, data read from the memory device 10 can output data with a bit width that is a multiple of 8 bits, such as 8 bits, 16 bits, 32 bits, 64 bits, 128 bits, 256 bits, 512 bits, 1024 bits, or 2048 bits, with a standard, which can be processed by the arithmetic device 300. In other words, the memory device 10 can be used for a general-purpose DRAM with 64 bits or 128 bits or a high bandwidth memory (HBM), for example.

The bus width of the bus wiring 200 electrically connecting the memory device 10 and the arithmetic device 300 is determined by a standard or the like, and data is input and output at high speed through an interface circuit or the like. A bit width of data read from the plurality of memory blocks 61 is preferably set in accordance with the bit width of the bus wiring 200.

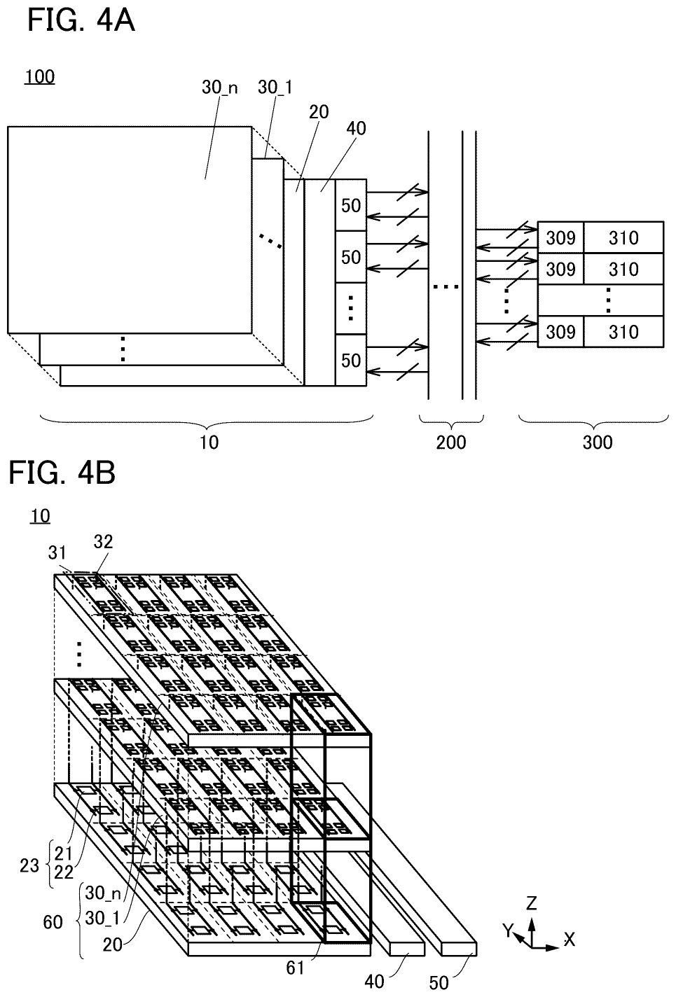

In the structure in which data with a large bit width can be output by increasing the parallel number of the memory blocks 61 in parallel, output of data between the memory device and the arithmetic device 300 through the bus wiring 200 is preferably performed at higher speed. For example, as illustrated in FIG. 4A, it is preferable to employ a structure in which the number of the input/output circuits 50 included in the memory device 10 is increased and a structure in which the number of the input/output circuits 309 and the number of the arithmetic portions 310, which are included in the arithmetic device 300, are increased. With the structure in which a plurality of input/output circuits 50 and a plurality of input/output circuits 309 are provided, a plurality of interface circuits for inputting/outputting data can be provided and the amount of data to be transmitted can be increased. When the number of the arithmetic portions 310 is increased, arithmetic processing can be performed at higher speed in case the amount of data is increased. Consequently, input and output of data between the memory device 10 and the arithmetic device 300 can be performed at high speed.

In the case where data is output in accordance with the bit width of the bus wiring 200 in the memory block 61, the memory density per unit area is preferably increased. For example, as illustrated in a block diagram and a perspective view illustrated in FIG. 4A and FIG. 4B, element layers 30_1 to 30_n (n is an integer greater than or equal to 2) are preferably provided as the element layer 30, and the cell array 31 formed using OS transistors is preferably stacked. In this case, the memory block array 60 including the memory block 61 is composed of the element layer 20 and the element layers 30_1 to 30_n.

When the element layers 30_1 to 30_n are stacked, that is, the element layers 30 are stacked, the cell arrays 31 can be stacked. The stacked element layers 30 are provided in the direction perpendicular to the surface of the substrate provided with the element layer 20 (z direction), whereby the memory density of the memory cells 32 can be improved. Moreover, the element layers 30 can be formed by repeating the same manufacturing process in the vertical direction. The manufacturing cost of the element layer 30 in the memory device 10 can be reduced.

Note that in FIG. 4A and FIG. 4B, a first element layer 30 is denoted by the element layer 30_1, a second element layer 30 is denoted by the element layer 30_2, and a third element layer 30 is denoted by the element layer 30_3. An n-th element layer 30 is denoted by the element layer 30_n. Note that in this embodiment and the like, the “element layer 30” is merely stated in some cases when describing a matter related to all the n element layers 30 or showing a matter common to the n element layers 30.

Note that as the number of layers of the element layers 30_1 to 30_n increases, the load capacitance of the bit line increases. In this case, it is preferable to employ a structure in which an element layer including an amplifier circuit having a function of amplifying and outputting a potential difference of data retained in the memory cell 32 is included between the element layer including the sense amplifier 22 and the element layer 30 including the memory cell 32.

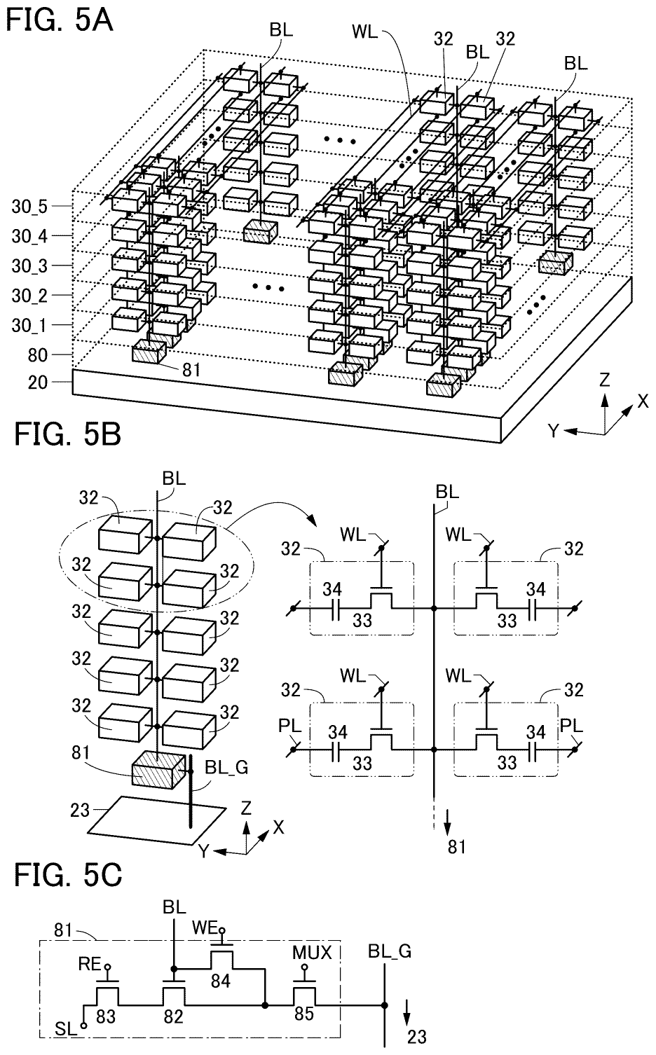

FIG. 5A illustrates, as an example, an element layer 80 including an amplifier circuit 81 provided between the element layer 20 and the stacked element layers 30_1 to 30_5. Like the element layer 30, the element layer 80 includes OS transistors. The amplifier circuit 81 is a circuit formed using OS transistors. FIG. 5A illustrates a word line WL provided to extend in the X direction and the bit line BL provided to extend in the Z direction. For easy viewing of the drawing, some of the wirings included in the element layers 30 are not illustrated.

FIG. 5B is a schematic view illustrating a structure example of the amplifier circuit 81 connected to the bit line BL (or the inverted bit line BLB) illustrated in FIG. 5A and the memory cells 32 included in the element layers 30_1 to 30_5 connected to the bit line BL. FIG. 5B illustrates a bit line BL_G provided between the amplifier circuit 81 and the reading circuit 23.

FIG. 5B illustrates an example of a circuit structure of the memory cell 32. The memory cell 32 illustrates a structure example of a DOSRAM including a transistor 33 and a capacitor 34.

The transistor 33 is preferably an OS transistor having a back gate that is not illustrated in FIG. 5B. Supplying constant voltage to the back gate of the transistor 33 allows control of transistor characteristics. The transistor 33 is an OS transistor provided in the element layer 30. The element layer 30 can be stacked over the element layer 20 including Si transistors; thus, the cell array 31 and the reading circuit 23 can be stacked.

The capacitor 34 has a function of retaining charge corresponding to data. Note that when the capacitor includes a ferroelectric material, the memory cell 32 can be used as a ferroelectric memory. For example, HfZrOₓ can be used as the ferroelectric material. Note that the term “HfZrOₓ” does not represent the stoichiometry of a hafnium atom, a zirconium atom, and an oxygen atom.

FIG. 5C is a circuit diagram illustrating the amplifier circuit 81. As illustrated in FIG. 5C, the amplifier circuit 81 includes transistors 82 to 85. The amplifier circuit 81 has a function of amplifying the potential of the bit line BL and transmitting the amplified potential to the bit line BL_G. The bit line BL_G is represented to be distinguished from other wirings functioning as bit lines. Signals WE, RE, and MUX are control signals for controlling the amplifier circuit 81. A wiring SL is a wiring for supplying a constant potential.

The structure illustrated in FIG. 5A to FIG. 5C includes the element layer 80 including the amplifier circuit 81 having a function of amplifying and outputting a data potential retained in the memory cell 32. With this structure, a slight difference in the potential of the bit line BL can be amplified at the time of data reading to drive the sense amplifier 22 included in the element layer 20. A circuit such as the sense amplifier 22 can be downsized, so that the memory device can be downsized. Moreover, even when the capacitance of the capacitors included in the memory cells 32 is reduced, operation is possible.

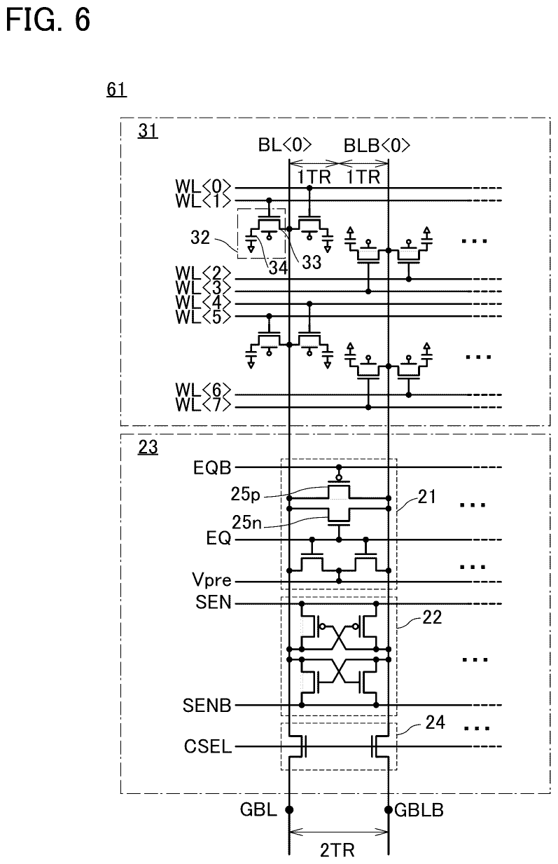

FIG. 6 is an example of a circuit diagram of the memory block 61 including the cell array 31 and the reading circuit 23. FIG. 6 illustrates a structure example of the memory cell 32 included in the cell array 31 and a structure example of the precharge circuit 21 and the sense amplifier 22 included in the reading circuit 23. In the example of FIG. 6, the number of memory cells per bit line BL in the cell array 31 is eight and the bit line pair (BL, BLB) is provided with respect to a global bit line pair (GBL, GBLB). The global bit line pair corresponds to a wiring pair to which data read by the sense amplifier 22 is output.

The memory cell 32 shows a structure example of the DOSRAM illustrated in FIG. 5B. FIG. 6 illustrates an example in which the memory cells 32 are electrically connected to word lines WL<0> to WL<7> and a bit line BL<0> (or an inverted bit line BLB<0>). As for reference numerals, while a reference numeral such as <1> is used to distinguish a plurality of components, reference numerals are omitted in the description in some cases.

Signals EQ, EQB, SEN, SENB, and CSEL and a voltage Vₚᵣₑ are input to the reading circuit 23. The signals EQB and SENB are inverted signals of the signals EQ and SEN, respectively. The transistors included in the reading circuit 23 are Si transistors. Thus, an n-channel transistor 25n and a p-channel transistor 25p can be employed.

The reading circuit 23 includes the precharge circuit 21 (also referred to as an equalizer), the sense amplifier 22, and a selector 24. The signals EQ and EQB are signals for activating the precharge circuit 21, and the signals SEN and SENB are signals for activating the sense amplifier 22. A signal CSEL is a signal for selecting whether to establish electrical continuity between any one of a plurality of bit line pairs and the global bit line pair (GBL, GBLB).

The reading circuit 23 illustrated in FIG. 6 includes a two-cell width (2TR) sense amplifier 22. A two-cell-width sense amplifier refers to a sense amplifier in which the width (interval) between the bit line pair (BL, BLB) is substantially equal to two memory cells. Note that the memory cell 32 is composed of 1TR1C and thus has a width of one transistor (1TR). That is, in the case where the sense amplifier 22 and the memory cell 32 are provided to overlap with each other, the cell array 31 electrically connected to the reading circuit 23 can be the cell array 31 connected to one of the bit line pairs (BL, BLB). In this case, the length of the bit line pair (BL, BLB) between the sense amplifier 22 and the memory cell 32 can be shortened.

When the length of the bit line pair (BL, BLB) is shortened, the bit line capacitance can be reduced. An index that affects reading performance is the ratio of the bit line capacitance (Cbit) to the capacitance Cs of the capacitor 34. With a higher Cs/Cbit, a larger potential difference of the bit line pair (BL, BLB) can be obtained when data is read from the memory cell 32. Therefore, a larger Cs/Cbit enables higher-speed or more stable reading operation. Under the condition where the reading performance is constant, a reduction in the bit line capacitance Cbit enables a reduction in the capacitance Cs of the capacitor 34. Therefore, in the case where the memory cell 32 is a DOSRAM and the capacitance Cs of the capacitor 34 is the same as the bit line capacitance Cbit, the memory cell 32 has excellent reading performance compared with a conventional DRAM using Si transistors.

In the case where the memory cell 32 is a DOSRAM, the OS transistor has an extremely low off-state current; thus, even when the capacitance Cs is smaller than that of a DRAM, the memory cell 32 has excellent retention characteristics compared with a conventional DRAM. Therefore, in the case where the memory cell 32 is a DOSRAM, the capacitance value of the capacitor of the memory cell can be smaller than the capacitance value of the capacitor of a DRAM, which is preferable.

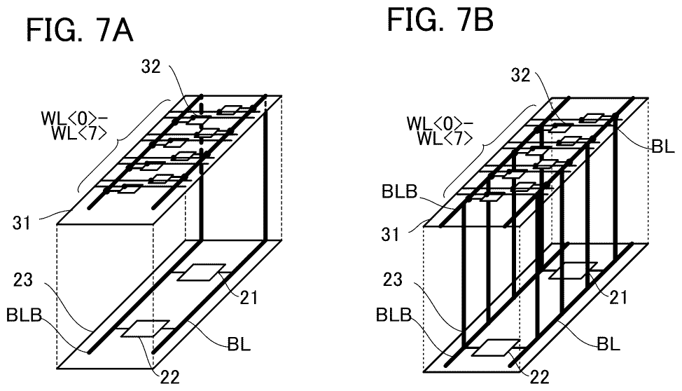

In the circuit diagram in FIG. 6, the bit line pair (BL, BLB) is illustrated to be led in each of the reading circuit 23 and the cell array 31; however, when the reading circuit 23 and the cell array 31 are stacked as illustrated in FIG. 7A, a portion where the bit line pair (BL, BLB) is led can be provided only in a region where the cell array 31 is provided. Note that although the word lines <0> to WL<7> and the bit line pair (BL, BLB) are illustrated to be orthogonal to each other on the surface where the memory cell 32 is provided in FIG. 7A, the word lines <0> to WL <7> and the bit line pair (BL, BLB) may be arranged to be oblique to each other. In this case, the region where the memory cell 32 is provided may also be arranged to be oblique with respect to the bit line pair (BL, BLB).

Note that in FIG. 7A, there is one portion where the bit line pair (BL, BLB) is led to connect the memory cell 32 and the sense amplifier 22 in the memory block 61, another structure may be employed. For example, as illustrated in FIG. 7B, a structure may be employed in which the bit line pair (BL, BLB) in the same layer as the memory cell 32 and the bit line pair (BL, BLB) in the same layer as the sense amplifier 22 are electrically connected to each other through a plurality of wirings.

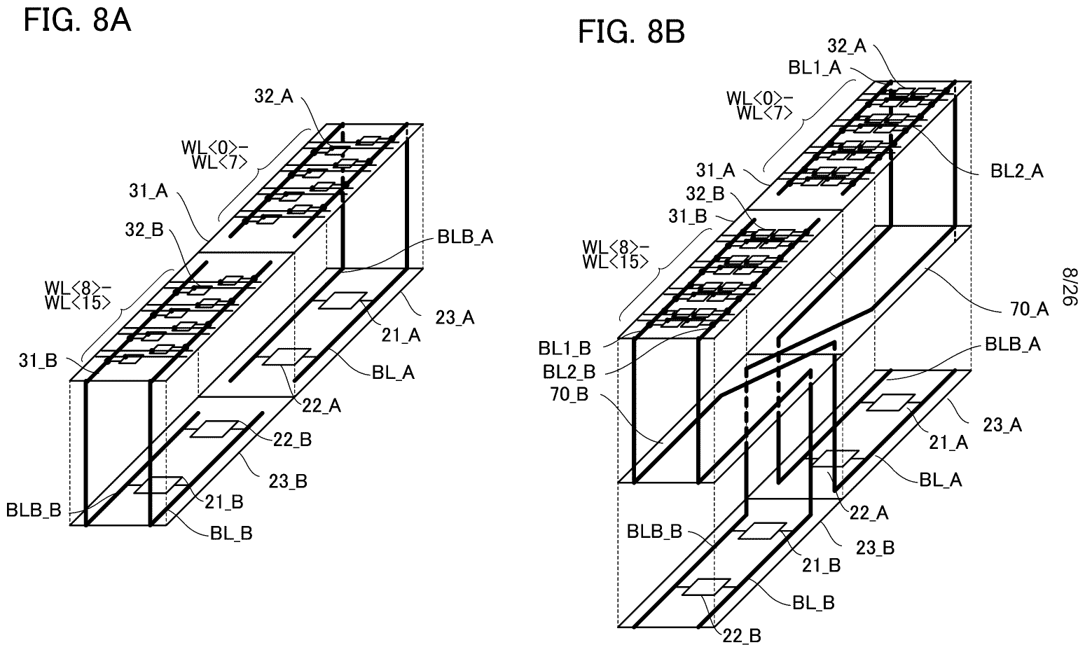

The adjacent cell arrays 31_A and 31_B and the adjacent reading circuits 23_A and 23_B can be arranged as illustrated in FIG. 8A. Note that FIG. 8A illustrates a structure in which memory cells 32_A in a cell array 31_A are connected to the word lines <0> to WL<7> and a bit line pair (BL_A, BLB_A). Similarly, FIG. 8A illustrates a structure in which memory cells 32_B in a cell array 31_B are connected to word lines <8> to WL<15> and a bit line pair (BL_B, BLB_B).

In the case of the structure in FIG. 8A, one memory cell 32 is preferably connected to one word line so that the bit line capacitance (load capacitance) to be loaded is substantially the same between bit line pairs (BL, BLB). Thus, in the structure in which the word lines and the bit line pairs are arranged orthogonally or obliquely, the memory cells 32 can be arranged in a zigzag manner and the memory cells 32 are not provided to be adjacent to each other. Therefore, it is further preferable that even when a plurality of memory cells are selected simultaneously by the word lines, bit line capacitance (load capacitance) to be loaded on the bit line pairs (BL, BLB) be substantially the same.

For example, as illustrated in FIG. 8B, wiring layers 70_A and 70_B are preferably provided. In FIG. 8B, the memory cell 32 is provided in each position where the word lines and the bit line pairs are orthogonal or oblique to each other. FIG. 8B illustrates a bit line pair (BL1_A, BL2_A) and bit lines (BL1_B, BL2_B), which are in the same layer as the memory cell 32 in memory blocks adjacent to each other. In the wiring layers 70_A and 70_B, the bit line BL2_A and the inverted bit line BLB_B are connected to each other. In the wiring layers 70_A and 70_B, the bit line BL1_B and the bit line BL_A are connected to each other. In the wiring layers 70_A and 70_B, the bit line BL2_B and the bit line BL_B are connected to each other.

With this structure, data of the memory cell 32_A included in the cell array 31_A selected by any one of the word lines <0> to WL<7> can be separately output to a sense amplifier 22_A and a sense amplifier 22_B. Similarly, data of the memory cell 32_B included in the cell array 31_B selected by any one of the word lines <8> to WL<15> can be separately output to the sense amplifier 22_A and the sense amplifier 22_B. In the sense amplifier 22_A and the sense amplifier 22_B, the load capacitance of the bit line pair (BL_A, BLB_A) and the bit line pair (BL_B, BLB_B) can be made substantially the same by the wiring layers 70_A and 70_B. Thus, the load capacitance values of the bit line pairs (BL, BLB) can be close to the same as each other, and the density of memory cells per unit area can be increased.

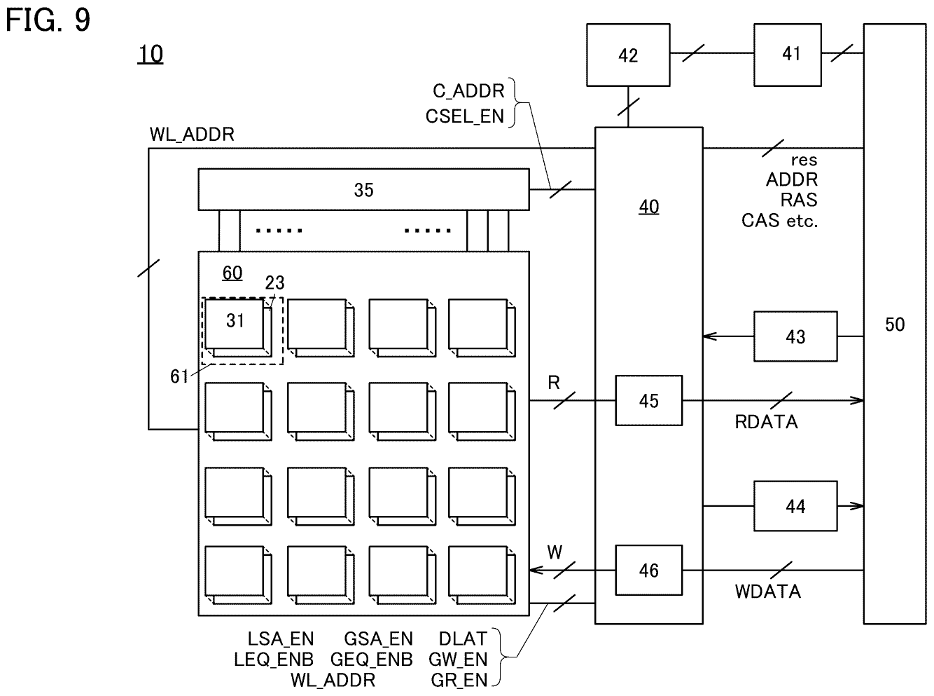

FIG. 9 is a block diagram of a more specific structure example of the memory device 10.

In the memory device 10 illustrated in FIG. 9, the input/output circuit 50, the control circuit 40, and the memory block array 60, which are described in FIG. 1A and the like, are illustrated.

FIG. 9 illustrates, as an example, an interface circuit I2C receiver 41, an LVDS circuit 43, and an LVDS circuit 44. Note that although the interface circuit having a structure different from that of the input/output circuit 50 is illustrated, the interface circuit may have a structure of part of the input/output circuit 50.

FIG. 9 illustrates, as an example, a setting register 42 and a decoder 35. In the memory block array 60 illustrated in FIG. 9, the plurality of memory blocks 61 are illustrated. As described above, the memory block 61 includes the cell array 31 provided in the element layer 20 and the reading circuit 23 provided in the element layer 30. The control circuit 40 includes a register 45 and a register 46.

The input/output circuit 50 has a function of delivering signals from/to an external device. Operation conditions and the like of the memory device 10 are determined by setting parameters stored in the setting register 42. The setting parameters are written into the setting register 42 through the input/output circuit 50 and the I2C receiver 41. Note that the I2C receiver 41 may be omitted depending on the purpose, the usage, or the like.

Examples of the setting parameters include designation information about execution intervals of refresh operations or timing of circuit operations, and the like. The control circuit 40 has a function of processing the setting parameters and a command signal from the outside and determining the operation mode of the memory device 10. The control circuit 40 has a function of generating a variety of control signals and controlling the operation of the whole memory device 10.

In addition, a reset signal res, an address signal ADDR, a row address identification signal RAS (Row Address Strobe), a column address identification signal CAS (Column Address Strobe) write data WDATA, and the like are supplied to the control circuit 40 from the outside through the input/output circuit 50. A clock signal for data writing is supplied to the control circuit through the LVDS circuit 43.

Read data RDATA is supplied from the control circuit 40 to the input/output circuit 50. A clock signal for data reading is supplied to the input/output circuit 50 through the LVDS circuit 44.

The write data WDATA is transmitted in synchronization with the clock signal for data writing and retained in the register 46 in the control circuit 40. The control circuit 40 has a function of supplying data W retained in the register 46 to the memory block array 60.

Data R read from the memory block array 60 is retained as the read data RDATA in the register 45 in the control circuit 40. The control circuit 40 has a function of transmitting the read data RDATA to the input/output circuit 50 in synchronization with the clock signal for data reading.

The control circuit 40 has a function of outputting a column address signal C_ADDR, a column selection enable signal CSEL_EN, a data latch signal DLAT, a global writing enable signal GW_EN, a global reading enable signal GR_EN, a global sense amplifier enable signal GSA_EN, a global equalization enable signal GEQ_ENB, a local sense amplifier enable signal LSA_EN, a local equalization enable signal LEQ_ENB, a word line address selection signal WL_ADDR, and the like.

The column address signal C_ADDR and the column selection enable signal CSEL_EN are supplied to the decoder 35.

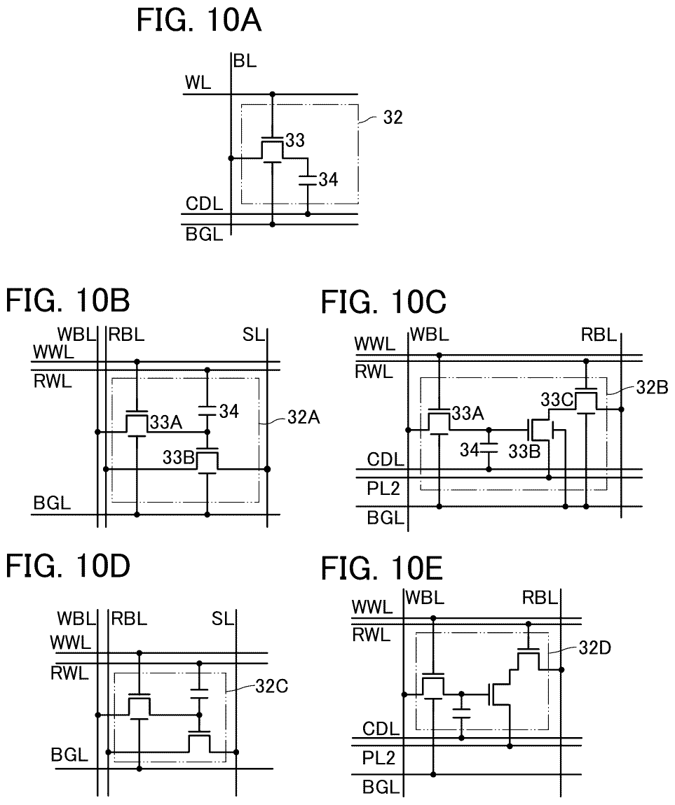

FIG. 10A to FIG. 10E are circuit diagrams each illustrating a structure example of a memory cell including an OS transistor that can be used for the memory cell 32 described above. As an example of the structure of the memory cell including an OS transistor, a DOSRAM or a NOSRAM can be given as described above.

FIG. 10A illustrates an example of a 1T1C (capacitor) DOSRAM memory cell that can be used as the memory cell 32. The memory cell 32 illustrated in FIG. 10A is electrically connected to the word line WL, the bit line BL, a capacitor line CDL, and a wiring BGL functioning as a wiring for supplying a back gate voltage. The memory cell 32 includes the transistor 33 and the capacitor 34. A back gate of the transistor 33 is electrically connected to the wiring BGL.

The transistor 33 is an OS transistor. The off-state current of an OS transistor is extremely low. Thus, the memory cell 32 can reduce the frequency of data refresh. Therefore, power required for data retention can be reduced.

FIG. 10B illustrates an example of a NOSRAM memory cell of a 2-transistor (2T) gain cell that can be used as the memory cell 32. A memory cell 32A illustrated in FIG. 10B includes transistors 33A and 33B and the capacitor 34. Note that the capacitor 34 included in the NOSRAM memory cell can be omitted when parasitic capacitance such as gate capacitance of a transistor is utilized. The transistor 33A is a write transistor and the transistor 33B is a read transistor. Back gates of the transistors 33A and 33B are electrically connected to the wiring BGL.

Since the write transistor is formed using an OS transistor, charge corresponding to data can be retained continuously by turning off the write transistor. Therefore, the memory cell 32A does not consume power for data retention. Thus, the memory cell 32A can function as a memory cell with low power consumption that can retain data for a long time.

Other structure examples of memory cells used for NOSRAMs are described with reference to FIG. 10C to FIG. 10E.

A memory cell 32B illustrated in FIG. 10C is a 3T gain cell and includes transistors 33A, 33B, and 33C and the capacitor 34. The transistors 33A, 33B, and 33C are a write transistor, a read transistor, and a selection transistor, respectively. Back gates of the transistors 33A, 33B and 33C are electrically connected to the wiring BGL. The memory cell 32B is electrically connected to word lines RWL and WWL, bit lines RBL and WBL, the capacitor line CDL, and a power supply line PL2. For example, a voltage GND (low-level-side power supply voltage) is input to the capacitor line CDL and the power supply line PL2.

FIG. 10D illustrates another structure example of a 2T gain cell. A memory cell 32C illustrated in FIG. 10D is different from the memory cell 32A illustrated in FIG. 10B in that the read transistor is formed using an OS transistor that does not have a back gate.

FIG. 10E illustrates another structure example of a 3T gain cell. A memory cell 32D illustrated in FIG. 10E is different from the memory cell 32A illustrated in FIG. 10B in that a read transistor and a selection transistor each include an OS transistor that does not have a back gate.

In the above-described gain cells, a bit line serving as both the wiring RBL and the wiring WBL may be provided.

In the case where the memory cell 32 is a DOSRAM or a NOSRAM, the wirings (the word lines WL and WWL in FIG. 10A to FIG. 10E) connected to the gates of the transistors (the transistors 33 and 33A in FIG. 10A to FIG. 10E) that are access transistors can be supplied with a voltage that turns off the transistors, and the other portions can be power gated. With this structure, the supply of power supply voltage can be stopped while data is stored in the memory cell 32.

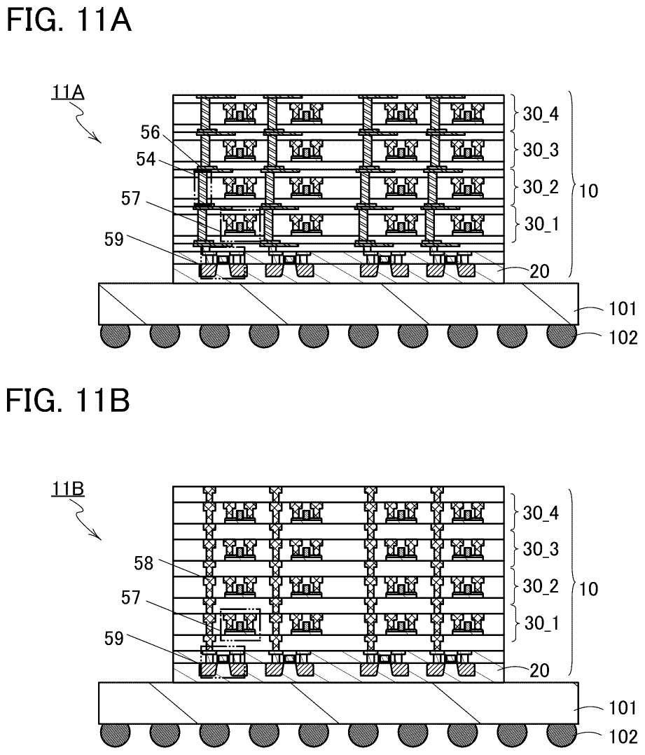

FIG. 11A and FIG. 11B are schematic views each illustrating a structure in which the above-described memory device 10 is used for an integrated circuit (referred to as an IC chip). The memory device 10 can be one IC chip by mounting a plurality of element layers on a package substrate. FIG. 11A and FIG. 11B each illustrate an example of the structure.

A schematic cross-sectional view of an IC chip 11A illustrated in FIG. 11A includes the element layer 20 to be a base die over a package substrate 101 and illustrates the memory device in which four element layers 30_1 to 30_4 are stacked over the element layer 20, for example. Solder balls 102 for connecting the memory device 10 to a printed circuit board or the like are provided on the packaging substrate 101. The element layers 30_1 to 30_4 are provided with through electrodes 54 provided to penetrate the element layers. The element layers 30_1 to 30_4 are attached to each other using electrodes 56 provided to be exposed on surfaces. As a technique for electrically bonding different layers using the electrodes 56, Cu—Cu bonding can be used. The Cu—Cu bonding is a technique that establishes electrical continuity by connecting Cu (copper) pads.

In the case where a plurality of element layers 30_1 to 30_4 are stacked three-dimensionally as illustrated in FIG. 11A, the element layers are electrically connected to each other by a technique using a through electrode such as a TSV (Through Silicon Via), a Cu—Cu direct bonding technique, or the like. With such a structure, signals and the like supplied to element layers can be distributed via wirings inside the element layers. Furthermore, a memory device applicable to the main memory can be changed into a memory using an OS transistor, so that power consumption can be reduced by utilizing the characteristics of extremely low off-state current of the OS transistor.

As another example, a schematic cross-sectional view of an IC chip 11B illustrated in FIG. 11B includes the element layer 20 to be a base die over the package substrate 101, and illustrates the memory device 10 where the four element layers 30_1 to 30_4 are stacked over the element layer 20, for example. Electrodes 58 for electrically connecting the element layer 20 and the element layers 30_1 to 30_4 can be provided in a step of manufacturing transistors 59, which are Si transistors, or transistors 57, which are OS transistors.

The schematic cross-sectional view of the IC chip 11B illustrated in FIG. 11B can be a monolithic structure where a technique using a through electrode such as a TSV or a Cu—Cu direct bonding technique is not used for connection between the element layer 20 including the transistors 59 and the element layers 30_1 to 30_4 including the transistors 57. The element layers 30_1 to 30_4 over the element layer 20 can have a structure where wirings provided together with the transistors 57 included in the element layers 30_1 to 30_4 are used as the electrodes 58 for connecting the element layers in the upper layers or the lower layers.

The intervals between the wirings provided together with the transistors 57 can be more miniaturized than those between through electrodes used for a TSV or a Cu—Cu direct bonding technique. Accordingly, in the structure of the IC chip 11B illustrated in FIG. 11B, the number of electrodes for connecting the element layers in the upper layers and the lower layers can be increased. Thus, the number of wirings (the number of signal lines) of the cell array 31 including the memory cells provided in the element layers 30_1 to 30_4 and the reading circuit 23 provided in the element layer 20 can be increased. Therefore, the transfer amount (bandwidth) of signals transmitted and received between the element layer 20 and the element layer 30 can be increased. Increasing the bandwidth can increase the data transfer amount between the cell array 31 and the reading circuit 23 per unit time.

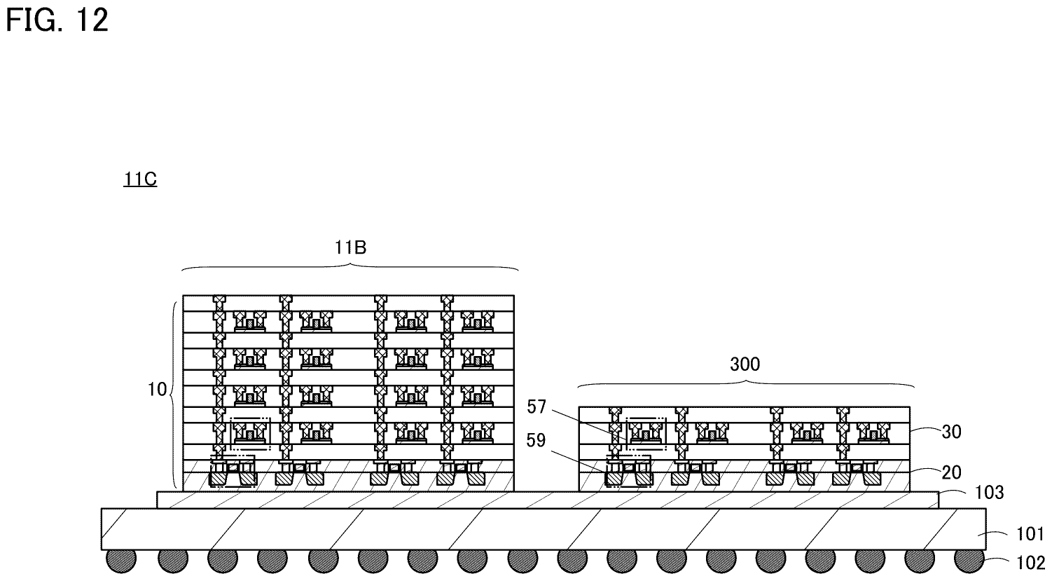

As another example, FIG. 12 illustrates a schematic view of an IC chip 11C in which another functional circuit such as the arithmetic device 300 is integrated with the IC chip 11B illustrated in FIG. 11B. In the structure illustrated in FIG. 12, the arithmetic device 300 and the memory device 10 can be manufactured in different steps and then provided over the same package substrate 101.

An interposer 103 provided with a wiring for electrically connecting the memory device included in the IC chip 11B and the arithmetic device 300 is provided over the package substrate 101. The wiring provided in the interposer 103 can function as the bus wiring 200. In addition to the memory device 10, the element layer 20 and the element layer 30 included in the arithmetic device 300 are illustrated over the interposer 103. The element layer 20 and the element layer 30 include the transistors 59, which are Si transistors, or the transistors 57, which are OS transistors.

In the schematic view of the IC chip 11C illustrated in FIG. 12, as a structure example of the arithmetic device 300, connection between the element layer 20 including the transistors 59 and the element layer 30 including the transistors 57 can be made by a technique using a through electrode such as a TSV or a Cu—Cu direct bonding technique, or the structure can be the monolithic structure illustrated in FIG. 11B.

In the structure example of the arithmetic device 300 illustrated in FIG. 12, in the case where the element layer 30 includes a circuit for retaining data including an OS transistor, the circuit can be a backup circuit for backing up data in a register included in the element layer 20 and the like. In this case, the OS transistor included in the element layer 30 is supplied with a voltage that turns off the transistor, whereby the circuit can function as a backup circuit. Thus, each of the circuits included in the element layer 20 can be power gated. With this structure, the supply of power supply voltage can be stopped while data is retained in the arithmetic device 300.

This embodiment can be implemented in combination with the other embodiments described in this specification as appropriate.

### Embodiment 2

In this embodiment, structures of transistors that can be used for the semiconductor device described in the above embodiment will be described. As an example, a structure in which transistors having different electrical characteristics are stacked will be described. With this structure, the design flexibility of a semiconductor device can be increased. In addition, providing transistors having different electrical characteristics to be stacked can increase the integration degree of the semiconductor device.

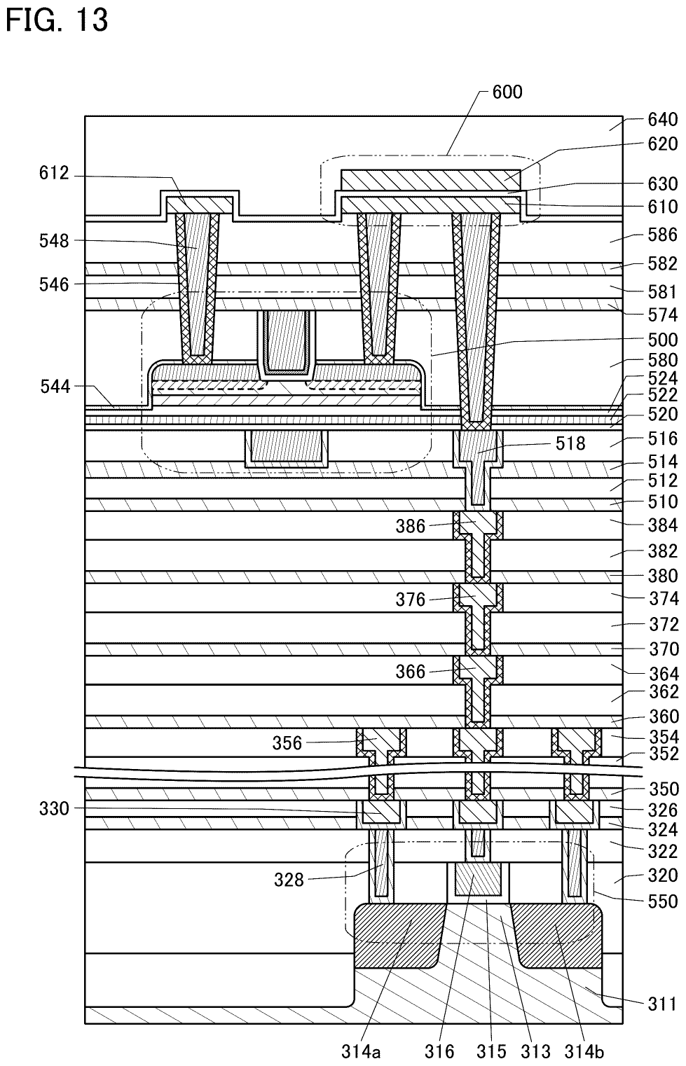

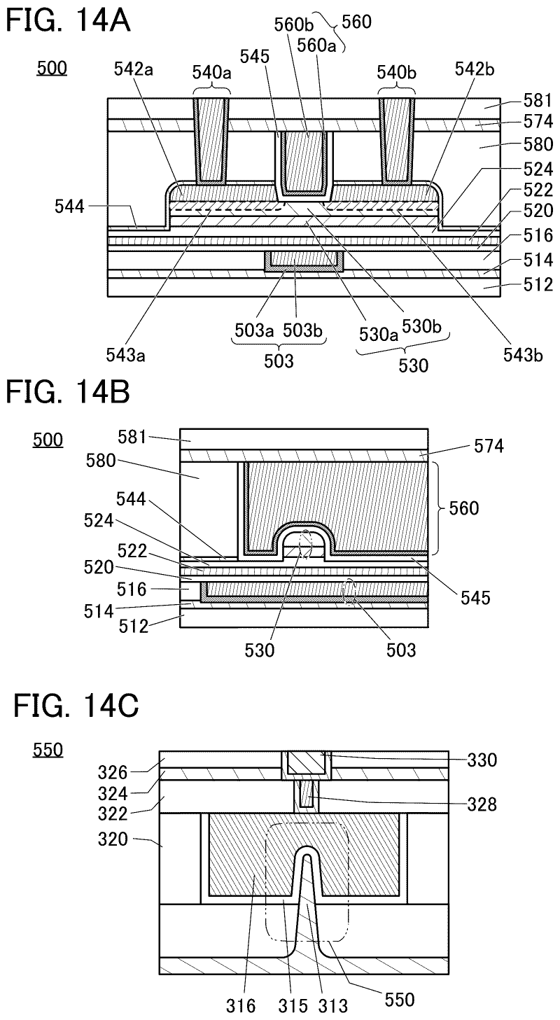

FIG. 13 illustrates part of a cross-sectional structure of a semiconductor device. The semiconductor device illustrated in FIG. 13 includes a transistor 550, a transistor 500, and a capacitor 600. FIG. 14A is a cross-sectional view of the transistor 500 in the channel length direction, FIG. 14B is a cross-sectional view of the transistor 500 in the channel width direction, and FIG. 14C is a cross-sectional view of the transistor 550 in the channel width direction. For example, the transistor 500 corresponds to the Si transistor described in the above embodiment, and the transistor 550 corresponds to an OS transistor.

In FIG. 13, the transistor 500 is provided above the transistor 550, and the capacitor 600 is provided above the transistor 550 and the transistor 500.

The transistor 550 is provided on a substrate 311 and includes a conductor 316, an insulator 315, a semiconductor region 313 that is part of the substrate 311, and a low-resistance region 314a and a low-resistance region 314b each functioning as a source region or a drain region.

As illustrated in FIG. 14C, the top surface and the side surface in the channel width direction of the semiconductor region 313 of the transistor 550 are covered with the conductor 316 with the insulator 315 therebetween. Such a Fin-type transistor 550 can have an increased effective channel width and thus have improved on-state characteristics. In addition, contribution of the electric field of a gate electrode can be increased, so that the off-state characteristics of the transistor 550 can be improved.

Note that the transistor 550 may be either a p-channel transistor or an n-channel transistor.

A region of the semiconductor region 313 where a channel is formed, a region in the vicinity thereof, the low-resistance region 314a and the low-resistance region 314b each functioning as a source region or a drain region, and the like preferably include a semiconductor such as a silicon-based semiconductor, and preferably include single crystal silicon. Alternatively, the regions may be formed using a material containing Ge (germanium), SiGe (silicon germanium), GaAs (gallium arsenide), GaAlAs (gallium aluminum arsenide), or the like. A structure using silicon whose effective mass is controlled by applying stress to a crystal lattice and changing lattice spacing may be employed. Alternatively, the transistor 550 may be a HEMT (High Electron Mobility Transistor) using GaAs and GaAlAs, or the like.

The low-resistance region 314a and the low-resistance region 314b include an element that imparts n-type conductivity, such as arsenic or phosphorus, or an element that imparts p-type conductivity, such as boron, in addition to the semiconductor material used for the semiconductor region 313.

For the conductor 316 functioning as a gate electrode, it is possible to use a semiconductor material such as silicon containing the element that imparts n-type conductivity, such as arsenic or phosphorus, or the element that imparts p-type conductivity, such as boron, or a conductive material such as a metal material, an alloy material, or a metal oxide material.

Note that since a work function depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten and aluminum for the conductor, and it is particularly preferable to use tungsten in terms of heat resistance.

The transistor 550 may be formed using an SOI (Silicon on Insulator) substrate or the like.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are sequentially stacked and provided to cover the transistor 550.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, aluminum nitride, or the like is used, for example.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may have a function of a planarization film for eliminating a level difference caused by the transistor 550 or the like provided therebelow. For example, the top surface of the insulator 322 may be planarized by planarization treatment using a chemical mechanical polishing (CMP) method or the like to have improved planarity.

For the insulator 324, it is preferable to use a film having a barrier property that prevents diffusion of hydrogen, impurities, or the like from the substrate 311, the transistor 550, or the like into a region where the transistor 500 is provided.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

The amount of released hydrogen can be measured by thermal desorption spectroscopy (TDS) or the like, for example. The amount of hydrogen released from the insulator 324 that is converted into hydrogen atoms per area of the insulator 324 is less than or equal to 1×10¹⁶ atoms/cm², preferably less than or equal to 5×10¹⁵ atoms/cm², in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. In addition, the relative permittivity of the insulator 326 is, for example, preferably 0.7 times or less, further preferably 0.6 times or less the relative permittivity of the insulator 324. When a material with low permittivity is used for the interlayer film, parasitic capacitance generated between wirings can be reduced.

A conductor 328, a conductor 330, and the like that are connected to the capacitor 600 or the transistor 500 are embedded in the insulator 320, the insulator 322, the insulator 324, and the insulator 326. Note that the conductor 328 and the conductor 330 each function as a plug or a wiring. A plurality of conductors functioning as plugs or wirings are collectively denoted by the same reference numeral in some cases. In this specification and the like, a wiring and a plug connected to the wiring may be a single component. That is, part of a conductor functions as a wiring in some cases and part of a conductor functions as a plug in other cases.

As a material for each of the plugs and wirings (the conductor 328, the conductor 330, and the like), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in FIG. 13. Furthermore, a conductor 356 is formed in the insulator 350, the insulator 352, and the insulator 354. The conductor 356 functions as a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. With this structure, the transistor 550 and the transistor 500 can be separated with a barrier layer, so that hydrogen diffusion from the transistor 550 into the transistor 500 can be inhibited.

Note that for the conductor having a barrier property against hydrogen, tantalum nitride or the like is preferably used, for example. By stacking tantalum nitride and tungsten, which has high conductivity, diffusion of hydrogen from the transistor 550 can be inhibited while the conductivity as a wiring is ensured. In that case, a tantalum nitride layer having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 13. Furthermore, a conductor 366 is formed in the insulator 360, the insulator 362, and the insulator 364. The conductor 366 functions as a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 13. Furthermore, a conductor 376 is formed in the insulator 370, the insulator 372, and the insulator 374. The conductor 376 functions as a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. With this structure, the transistor 550 and the transistor 500 can be separated with a barrier layer, so that hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 13. Furthermore, a conductor 386 is formed in the insulator 380, the insulator 382, and the insulator 384. The conductor 386 functions as a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. With this structure, the transistor 550 and the transistor 500 can be separated with a barrier layer, so that hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device according to this embodiment is not limited thereto. The number of wiring layers similar to the wiring layer including the conductor 356 may be three or less, or five or more.

An insulator 510, an insulator 512, an insulator 514, and an insulator 516 are sequentially stacked and provided over the insulator 384. A substance having a barrier property against oxygen, hydrogen, or the like is preferably used for any of the insulator 510, the insulator 512, the insulator 514, and the insulator 516.

For example, for each of the insulator 510 and the insulator 514, it is preferable to use a film having a barrier property that prevents diffusion of hydrogen, impurities, or the like from the substrate 311, a region where the transistor 550 is provided, or the like into a region where the transistor 500 is provided. Thus, a material similar to that for the insulator 324 can be used.

For the film having a barrier property against hydrogen, silicon nitride formed by a CVD method can be used, for example. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. The film that inhibits hydrogen diffusion is specifically a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents permeation of both oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide contained in the transistor 500 can be prevented. Therefore, aluminum oxide is suitably used for a protective film of the transistor 500.

The insulator 512 and the insulator 516 can be formed using a material similar to that for the insulator 320, for example. In the case where a material with a relatively low permittivity is used for these insulators, the parasitic capacitance between wirings can be reduced. A silicon oxide film, a silicon oxynitride film, or the like can be used as the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 functions as a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. In such a structure, the transistor 550 and the transistor 500 can be separated by a layer having a barrier property against oxygen, hydrogen, and water, so that the hydrogen diffusion from the transistor 550 into the transistor 500 can be inhibited.

The transistor 500 is provided over the insulator 516.

As illustrated in FIG. 14A and FIG. 14B, the transistor 500 includes the conductor 503 positioned to be embedded in the insulator 514 and the insulator 516; an insulator 520 positioned over the insulator 516 and the conductor 503; an insulator 522 positioned over the insulator 520; an insulator 524 positioned over the insulator 522; an oxide 530a positioned over the insulator 524; an oxide 530b positioned over the oxide 530a; a conductor 542a and a conductor 542b positioned apart from each other over the oxide 530b; an insulator 580 that is positioned over the conductor 542a and the conductor 542b and is provided with an opening formed to overlap a region between the conductor 542a and the conductor 542b; an insulator 545 positioned on the bottom surface and the side surface of the opening; and a conductor 560 positioned on a formation surface of the insulator 545.

In addition, as illustrated in FIG. 14A and FIG. 14B, an insulator 544 is preferably positioned between the insulator 580 and the oxide 530a, the oxide 530b, the conductor 542a, and the conductor 542b. Furthermore, as illustrated in FIG. 14A and FIG. 14B, the conductor 560 preferably includes a conductor 560a provided inside the insulator 545 and a conductor 560b provided to be embedded inside the conductor 560a. Moreover, as illustrated in FIG. 14A and FIG. 14B, an insulator 574 is preferably positioned over the insulator 580, the conductor 560, and the insulator 545.

In this specification and the like, the oxide 530a and the oxide 530b may be collectively referred to as an oxide 530.

Although the transistor 500 having, in the region where the channel is formed and its vicinity, a structure in which two layers of the oxide 530a and the oxide 530b are stacked is described, the present invention is not limited thereto. For example, a single layer structure of the oxide 530b or a stacked-layer structure of three or more layers may be provided.

Although the conductor 560 has a stacked-layer structure of two layers in the transistor 500, the present invention is not limited thereto. For example, the conductor 560 may have a single-layer structure or a stacked-layer structure of three or more layers. Furthermore, the transistor 500 illustrated in FIG. 13 and FIG. 14A is an example and the structure is not limited thereto; an appropriate transistor is used depending on a circuit structure, a driving method, or the like.

Here, the conductor 560 functions as a gate electrode of the transistor, and the conductor 542a and the conductor 542b function as a source electrode and a drain electrode. As described above, the conductor 560 is embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Therefore, the conductor 560 can be formed without an alignment margin, resulting in a reduction in the area occupied by the transistor 500. Accordingly, miniaturization and high integration of the semiconductor device can be achieved.

Since the conductor 560 is formed in the region between the conductor 542a and the conductor 542b in a self-aligned manner, the conductor 560 does not have a region overlapping with the conductor 542a or the conductor 542b. Thus, parasitic capacitance formed between the conductor 560 and each of the conductor 542a and the conductor 542b can be reduced. As a result, the transistor 500 can have increased switching speed and excellent frequency characteristics.

The conductor 560 functions as a first gate (also referred to as a top gate) electrode in some cases. The conductor 503 functions as a second gate (also referred to as a bottom gate) electrode in some cases. In that case, by changing a potential applied to the conductor 503 independently of a potential applied to the conductor 560, the threshold voltage of the transistor 500 can be controlled. In particular, when a negative potential is applied to the conductor 503, the threshold voltage of the transistor 500 can be higher than 0 V, and the off-state current can be reduced. Thus, a drain current when a potential applied to the conductor 560 is 0 V can be smaller in the case where a negative potential is applied to the conductor 503 than in the case where the negative potential is not applied to the conductor 503.

The conductor 503 is positioned to overlap with the oxide 530 and the conductor 560. Accordingly, in the case where potentials are applied to the conductor 560 and the conductor 503, an electric field generated from the conductor 560 and an electric field generated from the conductor 503 are connected, thereby covering the channel formation region in the oxide 530.

In this specification and the like, a transistor structure in which a channel formation region is electrically surrounded by the electric field of a first gate electrode is referred to as a surrounded channel (S-channel) structure. The S-channel structure disclosed in this specification and the like is different from a Fin structure or a planar structure. The S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or an LGAA (Lateral Gate All Around) structure. In the transistor having any of the S-channel structure, the GAA structure, and the LGAA structure, the channel formation region that is formed at the interface between the oxide 530 and the gate insulator or in the vicinity of the interface can be the entire bulk of the oxide 530. Consequently, the density of current flowing through the transistor can be improved, so that the on-state current or the field-effect mobility of the transistor can be expected to increase.

The conductor 503 has a structure similar to that of the conductor 518; a conductor 503a is formed in contact with an inner wall of the opening in the insulator 514 and the insulator 516, and a conductor 503b is formed on the inner side. Although the transistor 500 having a structure in which the conductor 503a and the conductor 503b are stacked is described, the present invention is not limited thereto. For example, the conductor 503 may have a single-layer structure or a stacked-layer structure of three or more layers.

The conductor 503a is preferably formed using a conductive material having a function of inhibiting diffusion of impurities such as a hydrogen atom, a hydrogen molecule, a water molecule, and a copper atom (a conductive material through which the above impurities are less likely to pass). Alternatively, the conductor 503a is preferably formed using a conductive material having a function of inhibiting diffusion of oxygen (e.g., at least one of oxygen atoms, oxygen molecules, and the like) (a conductive material through which the above oxygen is less likely to pass). Note that in this specification, a function of inhibiting diffusion of impurities or oxygen means a function of inhibiting diffusion of any one or all of the above impurities and the above oxygen.

For example, when the conductor 503a has a function of inhibiting diffusion of oxygen, the conductivity of the conductor 503b can be prevented from being lowered because of oxidation.

In the case where the conductor 503 also functions as a wiring, the conductor 503b is preferably formed using a conductive material with high conductivity that contains tungsten, copper, or aluminum as its main component. Although the conductor 503 has a stacked layer of the conductor 503a and the conductor 503b in this embodiment, the conductor 503 may have a single-layer structure.

The insulator 520, the insulator 522, and the insulator 524 function as a second gate insulating film.

Here, an insulator containing oxygen more than that in the stoichiometric composition is preferably used as the insulator 524 in contact with the oxide 530. Such oxygen is easily released from the film by heating. In this specification and the like, oxygen released by heating is sometimes referred to as “excess oxygen”. That is, a region containing excess oxygen (also referred to as an “excess-oxygen region”) is preferably formed in the insulator 524. When such an insulator containing excess oxygen is provided in contact with the oxide 530, oxygen vacancies (also referred to as Vo) in the oxide 530 can be reduced, leading to an improvement in reliability of the transistor 500. When hydrogen enters the oxygen vacancies in the oxide 530, such defects (hereinafter, referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that contains a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of a transistor. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with a sufficiently reduced amount of impurities such as VoH is used for the channel formation region of the transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸ atoms/cm³, preferably greater than or equal to 1.0×10¹⁹ atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. In the TDS analysis, the film-surface temperature is preferably higher than or equal to 100° C. and lower than or equal to 700° C., or higher than or equal to 100° C. and lower than or equal to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen to be H₂O, and is removed from the oxide 530 or an insulator in the vicinity of the oxide 530 in some cases. Some hydrogen may be gettered into the conductors 542a and 542b in some cases.

For the microwave treatment, for example, an apparatus including a power supply that generates high-density plasma or an apparatus including a power supply that applies RF to the substrate side is suitably used. For example, the use of an oxygen-containing gas and high-density plasma enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 530 to reduce oxygen vacancies (Vo). The heat treatment may be performed under reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas atmosphere or an inert gas atmosphere.

Note that the oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, the insulator 522 preferably has a function of inhibiting diffusion of oxygen (e.g., oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen contained in the oxide 530 to the insulator 520 side is prevented. In addition, the conductor 503 can be inhibited from reacting with oxygen in the insulator 524, the oxide 530, or the like.

The insulator 522 preferably has a single-layer structure or a stacked-layer structure using an insulator containing what is called a high-k material such as aluminum oxide, hafnium oxide, an oxide containing aluminum and hafnium (hafnium aluminate), tantalum oxide, zirconium oxide, lead zirconate titanate (PZT), strontium titanate (SrTiO₃), or (Ba, Sr)TiO₃ (BST), for example. With miniaturization and high integration of a transistor, a problem such as generation of an off-state current sometimes arises because of a thin gate insulating film. When a high-k material is used for an insulator functioning as the gate insulating film, a gate potential at the time of operating the transistor can be reduced while the physical thickness of the gate insulating film is kept.

It is particularly preferable to use an insulator containing an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide containing aluminum and hafnium (hafnium aluminate), or the like is preferably used as the insulator containing an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, combination of an insulator which is a high-k material and silicon oxide or silicon oxynitride enables the insulator 520 to have a stacked-layer structure that is thermally stable and has a high relative permittivity.

Note that in the transistor 500 in FIG. 14A and FIG. 14B, the insulator 520, the insulator 522, and the insulator 524 are illustrated as the second gate insulating film having a stacked-layer structure of three layers; however, the second gate insulating film may be a single layer or may have a stacked-layer structure of two layers or four or more layers. In that case, the stacked layers are not necessarily formed of the same material and may be formed of different materials.

In the transistor 500, a metal oxide functioning as an oxide semiconductor is used as the oxide 530 including a channel formation region.

The metal oxide functioning as an oxide semiconductor may be formed by a sputtering method or an ALD (Atomic Layer Deposition) method. Note that the metal oxide functioning as an oxide semiconductor will be described in detail in another embodiment.

The metal oxide functioning as the channel formation region in the oxide 530 has a band gap of 2 eV or more, preferably 2.5 eV or more. The use of a metal oxide having such a wide band gap can reduce the off-state current of a transistor.

When the oxide 530a is provided below the oxide 530b in the oxide 530, impurities can be inhibited from diffusing into the oxide 530b from the components formed below the oxide 530a.

The oxide 530 preferably has a structure including a plurality of oxide layers that differ in the atomic ratio of metal atoms. Specifically, the atomic ratio of an element M to constituent elements in the metal oxide used as the oxide 530a is preferably greater than that in the metal oxide used as the oxide 530b. Moreover, the atomic ratio of the element M to In in the metal oxide used as the oxide 530a is preferably greater than that in the metal oxide used as the oxide 530b. Moreover, the atomic ratio of In to the element M in the metal oxide used as the oxide 530b is preferably greater than that in the metal oxide used as the oxide 530a.

The energy of the conduction band minimum of the oxide 530a is preferably higher than that of the oxide 530b. In other words, the electron affinity of the oxide 530a is preferably smaller than that of the oxide 530b.

Here, the energy level of the conduction band minimum gradually changes at a junction portion of the oxide 530a and the oxide 530b. In other words, the energy level of the conduction band minimum at a junction portion of the oxide 530a and the oxide 530b is continuously varied or continuously connected. To change the energy level gradually, the density of defect states in a mixed layer formed at the interface between the oxide 530a and the oxide 530b is preferably made low.

Specifically, when the oxide 530a and the oxide 530b contain the same element (as a main component) in addition to oxygen, a mixed layer with a low density of defect states can be formed. For example, in the case where the oxide 530b is an In—Ga—Zn oxide, it is preferable to use an In—Ga—Zn oxide, a Ga—Zn oxide, gallium oxide, or the like as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Furthermore, a metal nitride film such as a tantalum nitride film is preferable because it has a barrier property against hydrogen or oxygen.

In addition, although the conductor 542a and the conductor 542b each having a single-layer structure are illustrated in FIG. 14A, a stacked-layer structure of two or more layers may be employed. For example, a tantalum nitride film and a tungsten film may be stacked. Alternatively, a titanium film and an aluminum film may be stacked. Other examples include a two-layer structure in which an aluminum film is stacked over a tungsten film, a two-layer structure in which a copper film is stacked over a copper-magnesium-aluminum alloy film, a two-layer structure in which a copper film is stacked over a titanium film, and a two-layer structure in which a copper film is stacked over a tungsten film.

Other examples include a three-layer structure of a titanium film or a titanium nitride film, an aluminum film or a copper film stacked over the titanium film or the titanium nitride film, and a titanium film or a titanium nitride formed thereover and a three-layer structure of a molybdenum film or a molybdenum nitride film, an aluminum film or a copper film stacked over the molybdenum film or the molybdenum nitride film, and a molybdenum film or a molybdenum nitride film formed thereover. Note that a transparent conductive material containing indium oxide, tin oxide, or zinc oxide may be used.

In addition, as illustrated in FIG. 14A, a region 543a and a region 543b are sometimes formed as low-resistance regions at and near an interface between the oxide 530 and the conductor 542a (the conductor 542b) and in the vicinity. In that case, the region 543a functions as one of a source region and a drain region, and the region 543b functions as the other of the source region and the drain region. A channel formation region is formed in a region sandwiched between the region 543a and the region 543b.

When the conductor 542a (the conductor 542b) is provided in contact with the oxide 530, the oxygen concentration in the region 543a (the region 543b) sometimes decrease. In addition, a metal compound layer that contains the metal contained in the conductor 542a (the conductor 542b) and the component of the oxide 530 is sometimes formed in the region 543a (the region 543b). In such cases, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover the side surface of the oxide 530 and to be in contact with the insulator 524.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 544. For the insulator 544, silicon nitride oxide or silicon nitride can be also used, for example.

It is particularly preferable to use, as the insulator 544, aluminum oxide, hafnium oxide, an oxide containing aluminum and hafnium (hafnium aluminate), or the like that is an insulator containing an oxide of one or both of aluminum and hafnium. In particular, hafnium aluminate has higher heat resistance than a hafnium oxide film. Therefore, hafnium aluminate is preferable because it is less likely to be crystallized by heat treatment in a later step. Note that the insulator 544 is not necessarily provided when the conductor 542a and the conductor 542b are oxidation-resistant materials or materials that do not significantly lose the conductivity even after absorbing oxygen. Design is determined as appropriate in consideration of required transistor characteristics.

The insulator 544 can inhibit impurities such as water and hydrogen contained in the insulator 580 from diffusing into the oxide 530b. Moreover, the oxidation of the conductor 542a and 542b due to excess oxygen contained in the insulator 580 can be inhibited.

The insulator 545 functions as a first gate insulating film. The insulator 545 is preferably formed using an insulator which contains excess oxygen and from which oxygen is released by heating, like the insulator 524.

Specifically, silicon oxide containing excess oxygen, silicon oxynitride, silicon nitride oxide, silicon nitride, silicon oxide to which fluorine is added, silicon oxide to which carbon is added, silicon oxide to which carbon and nitrogen are added, or porous silicon oxide can be used. In particular, silicon oxide and silicon oxynitride, which have thermal stability, are preferable.

When an insulator containing excess oxygen is provided as the insulator 545, oxygen can be effectively supplied from the insulator 545 to the channel formation region of the oxide 530b. As in the insulator 524, the concentration of impurities such as water or hydrogen in the insulator 545 is preferably reduced. The thickness of the insulator 545 is preferably greater than or equal to 1 nm and less than or equal to 20 nm.

Furthermore, in order that excess oxygen contained in the insulator 545 can be efficiently supplied to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, a reduction in the amount of excess oxygen supplied to the oxide 530 can be inhibited. Moreover, oxidation of the conductor 560 due to excess oxygen can be inhibited. For the metal oxide, a material that can be used for the insulator 544 is used.

Note that the insulator 545 may have a stacked-layer structure like the second gate insulating film. As miniaturization and high integration of transistors progress, a problem such as an off-state current might arise because of a thinner gate insulating film. For that reason, when the insulator functioning as the gate insulating film has a stacked-layer structure of a high-k material and a thermally stable material, a gate potential during transistor operation can be reduced while the physical thickness is maintained. Furthermore, the stacked-layer structure can be thermally stable and have a high relative permittivity.

Although the conductor 560 that functions as the first gate electrode and has a two-layer structure is illustrated in FIG. 14A and FIG. 14B, a single-layer structure or a stacked-layer structure of three or more layers may be employed.

The conductor 560a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, it is preferable to use a conductive material having a function of inhibiting diffusion of oxygen (e.g., at least one of an oxygen atom, an oxygen molecule, and the like). When the conductor 560a has a function of inhibiting diffusion of oxygen, the conductivity of the conductor 560b can be prevented from being lowered because of oxidation due to oxygen contained in the insulator 545. As a conductive material having a function of inhibiting diffusion of oxygen, for example, tantalum, tantalum nitride, ruthenium, ruthenium oxide, or the like is preferably used. For the conductor 560a, the oxide semiconductor that can be used as the oxide 530 can be used. In that case, when the conductor 560b is formed by a sputtering method, the conductor 560a can have a reduced electrical resistance value to be a conductor. Such a conductor can be referred to as an OC (Oxide Conductor) electrode.

Furthermore, the conductor 560b is preferably formed using a conductive material containing tungsten, copper, or aluminum as its main component. In addition, the conductor 560b also functions as a wiring and thus a conductor having high conductivity is preferably used. For example, a conductive material containing tungsten, copper, or aluminum as its main component can be used. The conductor 560b may have a stacked-layer structure, for example, a stacked-layer structure of titanium or titanium nitride and any of the above conductive materials.

The insulator 580 is provided over the conductor 542a and the conductor 542b with the insulator 544 therebetween. The insulator 580 preferably includes an excess-oxygen region. For example, the insulator 580 preferably contains silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride are preferable because they are thermally stable. Silicon oxide and porous silicon oxide are particularly preferable because an excess-oxygen region can be formed easily in a later step.

The insulator 580 preferably includes an excess-oxygen region. When the insulator 580 that releases oxygen by heating is provided, oxygen in the insulator 580 can be efficiently supplied to the oxide 530. Note that the concentration of impurities such as water or hydrogen in the insulator 580 is preferably reduced.

The opening of the insulator 580 is formed to overlap with a region between the conductor 542a and the conductor 542b. Thus, the conductor 560 is formed to be embedded in the opening of the insulator 580 and the region sandwiched between the conductor 542a and the conductor 542b.

The gate length needs to be short for miniaturization of the semiconductor device, but it is necessary to prevent a reduction in conductivity of the conductor 560. When the conductor 560 is made thick to achieve this, the conductor 560 might have a shape with a high aspect ratio. In this embodiment, the conductor 560 is provided to be embedded in the opening of the insulator 580; thus, even when the conductor 560 has a shape with a high aspect ratio, the conductor 560 can be formed without collapsing during the process.

The insulator 574 is preferably provided in contact with the top surface of the insulator 580, the top surface of the conductor 560, and the top surface of the insulator 545. When the insulator 574 is deposited by a sputtering method, excess-oxygen regions can be provided in the insulator 545 and the insulator 580. Therefore, oxygen can be supplied from the excess-oxygen regions to the oxide 530.

For example, a metal oxide containing one kind or two or more kinds selected from hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Thus, aluminum oxide deposited by a sputtering method can serve as not only an oxygen supply source but also a barrier film against impurities such as hydrogen.

An insulator 581 functioning as an interlayer film is preferably provided over the insulator 574. As in the insulator 524 or the like, the concentration of impurities such as water or hydrogen in the insulator 581 is preferably reduced.

A conductor 540a and a conductor 540b are provided in openings formed in the insulator 581, the insulator 574, the insulator 580, and the insulator 544. The conductor 540a and the conductor 540b are provided to face each other with the conductor 560 therebetween. The conductor 540a and the conductor 540b have a structure similar to that of a conductor 546 and a conductor 548 described later.

An insulator 582 is provided over the insulator 581. A material having a barrier property against oxygen, hydrogen, or the like is preferably used for the insulator 582. Thus, the insulator 582 can be formed using a material similar to that for the insulator 514. For the insulator 582, a metal oxide such as aluminum oxide, hafnium oxide, or tantalum oxide is preferably used, for example.

In particular, aluminum oxide has an excellent blocking effect that prevents permeation of both oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide contained in the transistor 500 can be prevented. Therefore, aluminum oxide is suitably used for a protective film of the transistor 500.

An insulator 586 is provided over the insulator 582. The insulator 586 can be formed using a material similar to that for the insulator 320. In the case where a material with a relatively low permittivity is used for these insulators, the parasitic capacitance generated between wirings can be reduced. A silicon oxide film, a silicon oxynitride film, or the like can be used for the insulator 586, for example.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 function as plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as some of the manufacturing steps of the transistor 500. The insulator having a high barrier property against hydrogen or water is formed using a material similar to that for the insulator 522 or the insulator 514, for example.

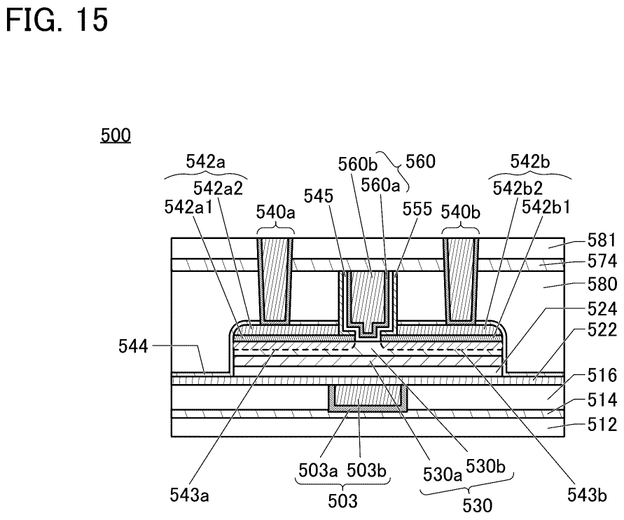

Note that the transistor that can be used in the present invention is not limited to the transistor 500 illustrated in FIG. 14A and FIG. 14B. For example, the transistor 500 having the structure illustrated in FIG. 15 may be used. The transistor 500 illustrated in FIG. 15 is different from the transistor illustrated in FIG. 14A and FIG. 14B in that the insulator 555 is used and the conductor 542a (a conductor 542al and a conductor 542a2) and the conductor 542b (a conductor 542b1 and a conductor 542b2) each have a stacked-layer structure.

The conductor 542a has a stacked structure of the conductor 542al and the conductor 542a2 over the conductor 542al, and the conductor 542b has a stacked structure of the conductor 542b1 and the conductor 542b2 over the conductor 542b1. The conductor 542al and the conductor 542b1 in contact with the oxide 530b are preferably conductors that are less likely to be oxidized, such as metal nitride. In that case, the conductor 542a and the conductor 542b can be prevented from being oxidized excessively due to oxygen contained in the oxide 530b. The conductor 542a2 and the conductor 542b2 are preferably conductors having higher conductivity than the conductor 542al and the conductor 542b1, such as a metal layer. Accordingly, the conductor 542a and the conductor 542b can each function as a wiring or an electrode having high conductivity. In this manner, a semiconductor device in which the conductor 542a and the conductor 542b each function as a wiring or an electrode are provided in contact with the top surface of the oxide 530 functioning as an active layer can be provided.

As the conductors 542al and 542b1, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

The conductor 542a2 and the conductor 542b2 preferably have higher conductivity than the conductor 542al and the conductor 542b1. For example, the thicknesses of the conductor 542a2 and the conductor 542b2 are preferably larger than the thicknesses of the conductor 542al and the conductor 542b1. As the conductor 542a2 and the conductor 542b2, a conductor that can be used as the conductor 560b can be used. The above structure can reduce the resistance of the conductor 542a2 and the conductor 542b2.

For example, tantalum nitride or titanium nitride can be used for the conductor 542al and the conductor 542b1, and tungsten can be used for the conductor 542a2 and the conductor 542b2.

As illustrated in FIG. 15, in a cross-sectional view of the transistor 500 in the channel length direction, the distance between the conductor 542al and the conductor 542b1 is preferably smaller than the distance between the conductor 542a2 and the conductor 542b2. With such a structure, the distance between the source and the drain can be shortened, and the channel length can be accordingly shortened. Thus, the frequency characteristics of the transistor 500 can be improved. In this manner, miniaturization of the semiconductor device enables the semiconductor device to have a higher operation speed.

The insulator 555 is preferably an insulator that is less likely to be oxidized, such as nitride. The insulator 555 is formed in contact with the side surface of the conductor 542a2 and the side surface of the conductor 542b2 and has a function of protecting the conductor 542a2 and the conductor 542b2. The insulator 555 is preferably an inorganic insulator that is less likely to be oxidized because it is exposed to an oxidation atmosphere. Since the insulator 555 is in contact with the conductor 542a2 and the conductor 542b2, the insulator 555 is preferably an inorganic insulator that is less likely to oxidize the conductors 542a2 and 542b2. Therefore, for the insulator 555, an insulating material having a barrier property against oxygen is preferably used. For the insulator 555, silicon oxynitride can be used.

The transistor 500 illustrated in FIG. 15 is formed in the following manner: an opening is formed in the insulator 580 and the insulator 544, the insulator 555 is formed in contact with a sidewall of the opening, and then the conductors 542al and 542b1 are separated using a mask. The opening and a region between the conductor 542a2 and the conductor 542b2 overlap with each other. The conductor 542al and the conductor 542b1 are formed to partly extend in the opening. Thus, the insulator 555 is in contact with the top surface of the conductor 542a1, the top surface of the conductor 542b1, the side surface of the conductor 542a2, and the side surface of the conductor 542b2 in the opening. The insulator 545 is in contact with the top surface of the oxide 530 in a region between the conductor 542al and the conductor 542b1.

Heat treatment in an atmosphere containing oxygen is preferably performed after the separation of the conductor 542al and the conductor 542b1 and before the formation of the insulator 545. Accordingly, oxygen can be supplied to the oxide 530a and the oxide 530b to reduce oxygen vacancies. Furthermore, since the insulator 555 is formed in contact with the side surface of the conductor 542a2 and the side surface of the conductor 542b2, excessive oxidation of the conductor 542a2 and the conductor 542b2 can be prevented. Accordingly, the transistor can have improved electrical characteristics and reliability. In addition, variations in electrical characteristics of transistors formed over the same substrate can be reduced.

In the transistor 500, the insulator 524 may be formed into an island shape, as illustrated in FIG. 15. Here, the insulator 524 may be formed so that the side end portion thereof is substantially aligned with the side end portion of the metal oxide 530.

In the transistor 500, the insulator 522 may be in contact with the insulator 516 and the conductor 503, as illustrated in FIG. 15. In other words, the insulator 520 illustrated in FIG. 14A and FIG. 14B may be omitted.

The capacitor 600 is provided above the transistor 500. The capacitor 600 includes a conductor 610, a conductor 620, and an insulator 630.

A conductor 612 may be provided over the conductor 546 and the conductor 548. The conductor 612 functions as a plug or a wiring that is connected to the transistor 500. The conductor 610 functions as an electrode of the capacitor 600. The conductor 612 and the conductor 610 can be formed at the same time.

The conductor 612 and the conductor 610 can be formed using a metal film containing an element selected from molybdenum, titanium, tantalum, tungsten, aluminum, copper, chromium, neodymium, and scandium; a metal nitride film containing any of the above elements as its component (a tantalum nitride film, a titanium nitride film, a molybdenum nitride film, or a tungsten nitride film); or the like. Alternatively, it is possible to use a conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added.

Although the conductor 612 and the conductor 610 each having a single-layer structure are described in this embodiment, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 therebetween. Note that the conductor 620 can be formed using a conductive material such as a metal material, an alloy material, or a metal oxide material. It is preferable to use a high-melting-point material that has both heat resistance and conductivity, such as tungsten or molybdenum, and it is particularly preferable to use tungsten. In the case where the conductor 620 is formed concurrently with another component such as a conductor, Cu (copper), Al (aluminum), or the like, which is a low-resistance metal material, may be used.

An insulator 640 is provided over the conductor 620 and the insulator 630. The insulator 640 can be formed using a material similar to that for the insulator 320. In addition, the insulator 640 may function as a planarization film that covers an uneven shape thereunder.

With the use of the structure, a semiconductor device that includes a transistor including an oxide semiconductor can be miniaturized or highly integrated.

As a substrate that can be used for the semiconductor device of one embodiment of the present invention, a glass substrate, a quartz substrate, a sapphire substrate, a ceramic substrate, a metal substrate (e.g., a stainless steel substrate, a substrate including stainless steel foil, a tungsten substrate, a substrate including tungsten foil, or the like), a semiconductor substrate (e.g., a single crystal semiconductor substrate, a polycrystalline semiconductor substrate, a compound semiconductor substrate, or the like), an SOI (Silicon on Insulator) substrate, or the like can be used. Alternatively, a plastic substrate having heat resistance to the processing temperature in this embodiment may be used. Examples of a glass substrate include barium borosilicate glass, aluminosilicate glass, aluminoborosilicate glass, and soda lime glass. Alternatively, crystallized glass or the like can be used.

Alternatively, a flexible substrate, an attachment film, paper or a base film including a fibrous material, or the like can be used as the substrate. As examples of the flexible substrate, the attachment film, the base material film, and the like, the following can be given. Examples include plastics typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Alternatively, polyamide, polyimide, an aramid resin, an epoxy resin, an inorganic vapor deposition film, and paper can be used. Specifically, the use of a semiconductor substrate, a single crystal substrate, an SOI substrate, or the like enables the manufacture of small-sized transistors with a small variation in characteristics, size, shape, or the like and with high current capability. A circuit using such transistors achieves lower power consumption or higher integration.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. The separation layer can be used when part or the whole of a semiconductor device formed over the separation layer is separated from the substrate and transferred to another substrate. In such a case, the transistor, the resistor, the capacitor, and/or the like can be transferred to a substrate having low heat resistance, a flexible substrate, or the like. Note that as the separation layer, a stacked-layer structure of a tungsten film and a silicon oxide film that are inorganic films, a structure in which an organic resin film of polyimide or the like is formed over a substrate, a silicon film containing hydrogen, or the like can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured, high heat resistance can be provided, or a reduction in weight or thickness can be achieved.

Providing a semiconductor device over a flexible substrate can inhibit an increase in weight and allows the provided semiconductor device to be robust.

Note that the transistor 550 illustrated in FIG. 13 is an example and the structure is not limited thereto; an appropriate transistor is used depending on a circuit structure, a driving method, or the like. For example, when the semiconductor device is a single-polarity circuit using only OS transistors (which mean transistors having the same polarity, e.g., only n-channel transistors), the transistor 550 has a structure similar to that of the transistor 500.

The configuration, structure, method, and the like described in this embodiment can be used in appropriate combination with the configurations, structures, methods, and the like described in the other embodiments, examples, and the like.

### Embodiment 3

In this embodiment, a cross-sectional structure example of stacked element layers that include OS transistors and can be used for a memory device or the like is described. In this embodiment, an example of a schematic cross-sectional view that can be used for a circuit structure such as a DOSRAM or a NOSRAM is described.

### <Structure Example 1 of DOSRAM>

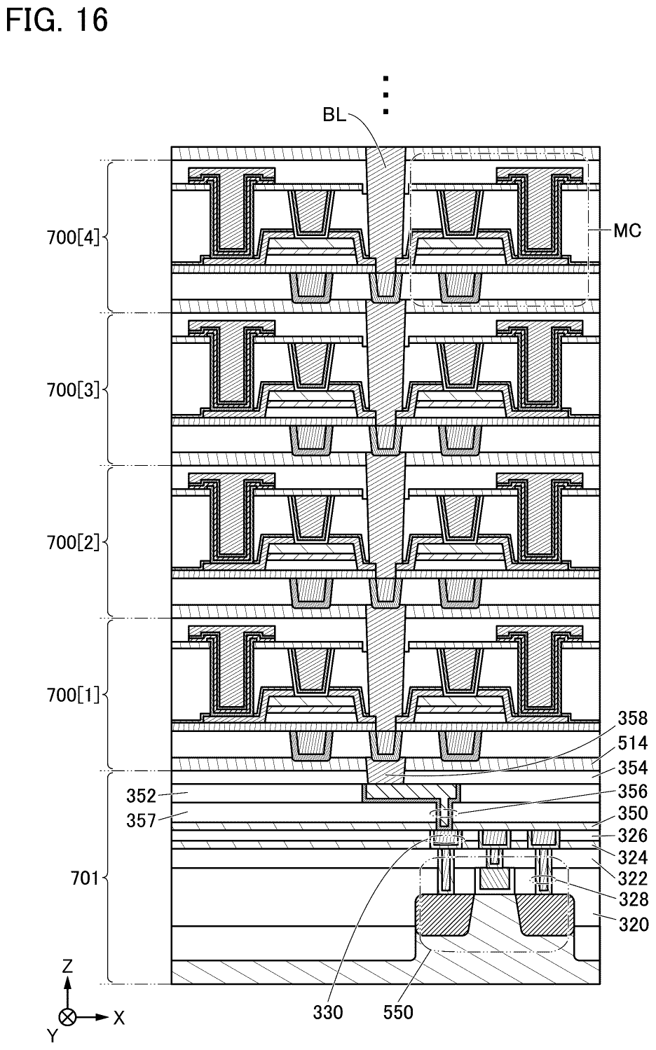

FIG. 16 illustrates a cross-sectional structure example of the case of using a DOSRAM circuit structure. In the example illustrated in FIG. 16, an element layer 700[1] to an element layer 700[4] are stacked over an element layer 701.

FIG. 16 illustrates the transistor 550 included in the element layer 701 as an example. The transistor 550 described in the above embodiment can be used as the transistor 550.

The transistor 550 illustrated in FIG. 16 is an example and the structure is not limited thereto; an appropriate transistor can be used depending on a circuit structure, a driving method, or the like.

A wiring layer provided with an interlayer film, a wiring, a plug, and the like may be provided between the element layer 701 and the element layer 700 or between a k-th element layer 700 and a k+1-th element layer 700. In this embodiment and the like, the k-th element layer 700 is referred to as an element layer 700[k], and the k+1-th element layer 700 is referred to as an element layer 700[k+1], in some cases. Here, k is an integer greater than or equal to 1 and less than or equal to N. In this embodiment and the like, the solutions of “k+α (α is an integer greater than or equal to 1)” and “k-α” are each an integer greater than or equal to 1 and less than or equal to N.

A plurality of wiring layers can be provided in accordance with design. Furthermore, in this specification and the like, a wiring and a plug electrically connected to the wiring may be a single component. That is, part of a conductor functions as a wiring in some cases, and part of a conductor functions as a plug in other cases.

For example, the insulator 320, the insulator 322, the insulator 324, and the insulator 326 are stacked in this order over the transistor 550 as interlayer films. The conductor 328 or the like is embedded in the insulator 320 and the insulator 322. The conductor 330 or the like is embedded in the insulator 324 and the insulator 326. Note that the conductor 328 and the conductor 330 each function as a contact plug or a wiring.

The insulator functioning as an interlayer film may also function as a planarization film that covers an uneven shape thereunder. For example, the top surface of the insulator 320 may be planarized by planarization treatment using a CMP method or the like to improve planarity.

A wiring layer may be provided over the insulator 326 and the conductor 330. For example, in FIG. 16, the insulator 350, an insulator 357, the insulator 352, and the insulator 354 are stacked in this order over the insulator 326 and the conductor 330. The conductor 356 is formed in the insulator 350, the insulator 357, and the insulator 352. The conductor 356 functions as a contact plug or a wiring.

Over the insulator 354, the insulator 514 included in the element layer 700[1] is provided. A conductor 358 is embedded in the insulator 514 and the insulator 354. The conductor 358 functions as a contact plug or a wiring. For example, the bit line BL and the transistor 550 are electrically connected to each other through the conductor 358, the conductor 356, the conductor 330, and the like.

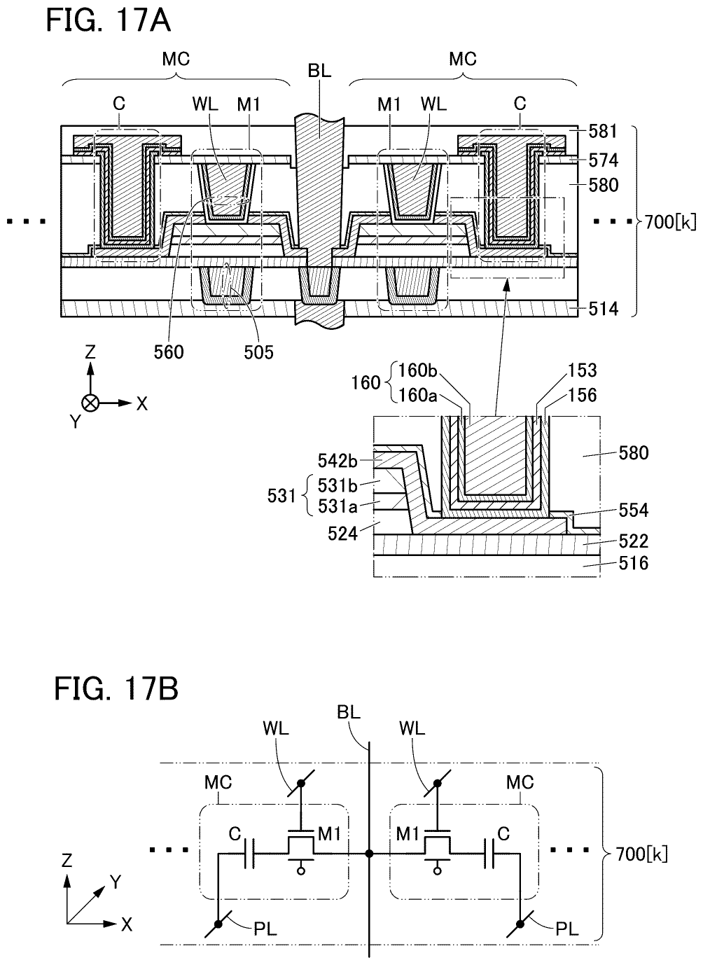

FIG. 17A illustrates a cross-sectional structure example of the element layer 700[k]. In addition, FIG. 17B illustrates an equivalent circuit diagram of FIG. 17A. FIG. 17A illustrates an example where two memory cells MC are electrically connected to one bit line BL.

The memory cell MC illustrated in FIG. 16 and FIG. 17A includes a transistor M1 and a capacitor C. As the transistor M1, the transistor 500 described in the above embodiment can be used, for example.

In this embodiment, a modification example of the transistor 500 is described as the transistor M1. Specifically, the transistor M1 is different from the transistor 500 in that the conductor 542a and the conductor 542b extend beyond the end portion of a metal oxide 531 (a metal oxide 531a and a metal oxide 531b).

The memory cell MC illustrated in FIG. 16 and FIG. 17A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. Furthermore, the conductor 160 is electrically connected to a wiring PL (not illustrated in FIG. 17A).

The capacitor C is formed in an opening portion that is provided by removal of part of the insulator 574, part of the insulator 580, and part of an insulator 554. The conductor 156, the insulator 580, and the insulator 554 are formed along the side surface of the opening portion, and thus are preferably deposited by an ALD method, a CVD method, or the like.

The conductor 156 and the conductor 160 may be formed using a conductor that can be used for a conductor 505 or the conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

As the insulator 153, an insulator of a high permittivity (high-k) material (material with a high relative permittivity) is preferably used. As the insulator of a high permittivity material, an oxide, an oxynitride, a nitride oxide, or a nitride containing one or more kinds of metal element selected from aluminum, hafnium, zirconium, gallium, and the like can be used, for example. The above-described oxide, oxynitride, nitride oxide, or nitride may include silicon. Insulating layers each formed of any of the above-described materials can be stacked to be used. As the insulator 153, a stacked-layer structure of three layers of zirconium oxide, aluminum oxide, and zirconium oxide is given for example. Note that the stacked-layer structure of the three layers may be referred to as ZrOₓₐ\AlO_{xb}\ZrO_{xc}(ZAZ). Note that xa, xb, and xc described above are each a given unit.

As the insulator of high permittivity material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, an oxynitride containing hafnium and zirconium, or the like can be used, for example. Using such a high permittivity material allows the insulator 153 to be thick enough to inhibit an off-state current and a sufficiently high capacitance of the capacitor C to be ensured.

It is preferable to use stacked insulating layers each formed of any of the above-described materials. A stacked-layer structure using a high permittivity material and a material having higher dielectric strength than the high permittivity material is preferably used. For example, as the insulator 153, an insulating film in which zirconium oxide, aluminum oxide, and zirconium oxide are stacked in this order can be used. Alternatively for example, an insulating film in which zirconium oxide, aluminum oxide, zirconium oxide, and aluminum oxide are stacked in this order can be used. Alternatively for example, an insulating film in which hafnium zirconium oxide, aluminum oxide, hafnium zirconium oxide, and aluminum oxide are stacked in this order can be used. The use of stacked insulators with relatively high dielectric strength, such as aluminum oxide, can increase the dielectric strength and inhibit electrostatic breakdown of the capacitor C.

### <Structure Example of NOSRAM>

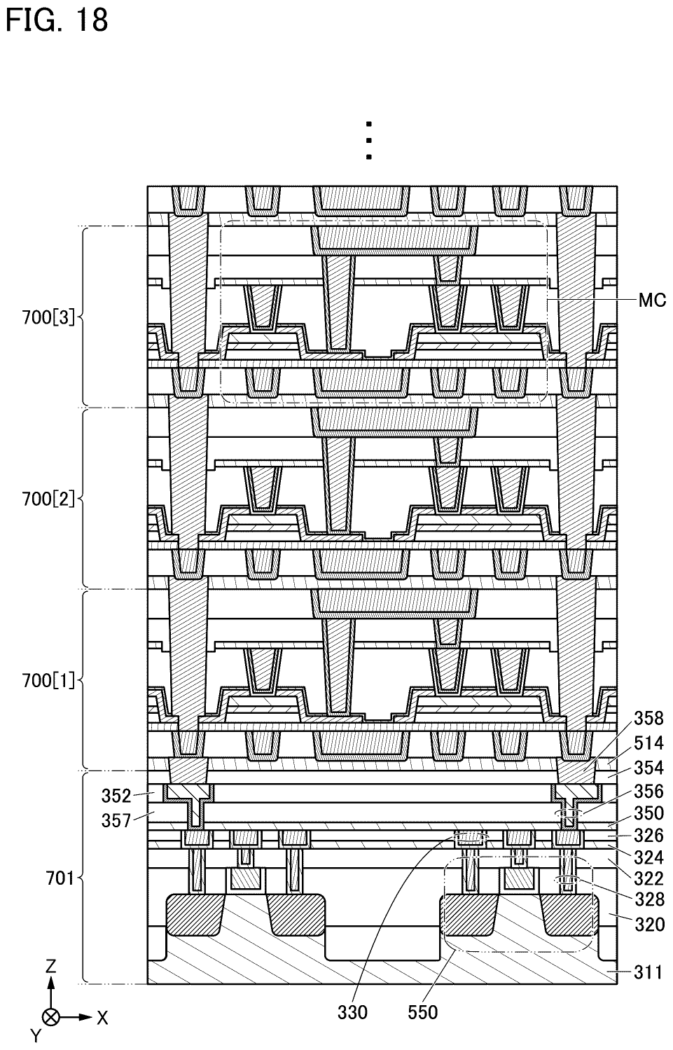

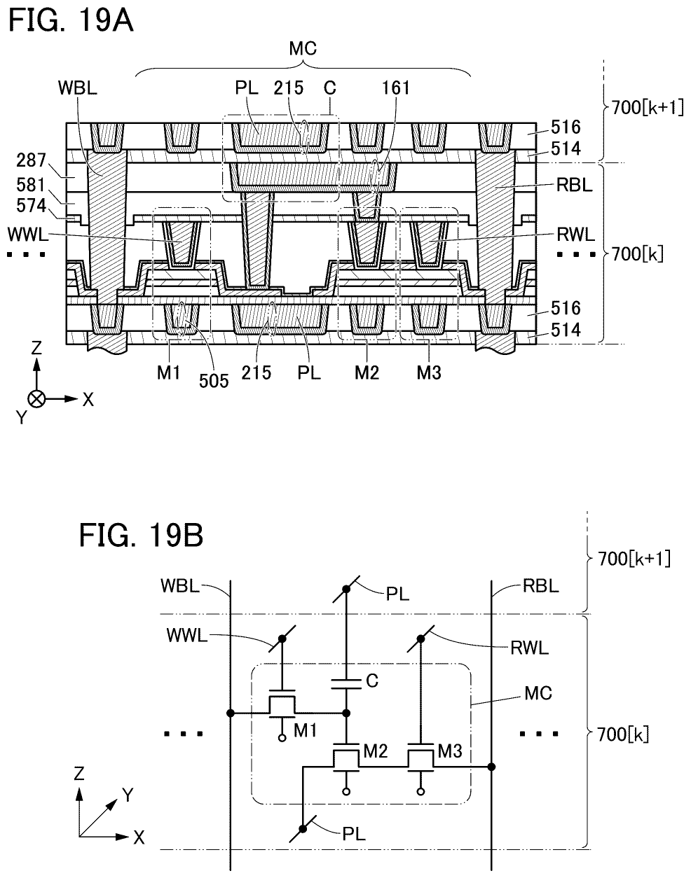

FIG. 18 illustrates a cross-sectional structure example of the case of using a NOSRAM memory cell circuit structure. Note that FIG. 18 is also a modification example of FIG. 16. FIG. 19A illustrates a cross-sectional structure example of the element layer 700[k]. Furthermore, FIG. 19B illustrates an equivalent circuit diagram of FIG. 19A.

The memory cell MC illustrated in FIG. 18 and FIG. 19A includes the transistor M1, a transistor M2, and a transistor M3 over the insulator 514. A conductor 215 is provided over the insulator 514. The conductor 215 can be formed using the same material in the same process as those of the conductor 505 at the same time.

The transistor M2 and the transistor M3 illustrated in FIG. 18 and FIG. 19A share one island-shaped metal oxide 531. In other words, a part of the one island-shaped metal oxide 531 functions as a channel formation region of the transistor M2, and another part thereof functions as a channel formation region of the transistor M3. Furthermore, the source of the transistor M2 and a drain of the transistor M3 are shared, or the drain of the transistor M2 and a source of the transistor M3 are shared. Thus, the area occupied by the transistor M2 and the transistor M3 is smaller than that of the case where the transistors are independently provided.

In the memory cell MC illustrated in FIG. 18 and FIG. 19A, an insulator 287 is provided over the insulator 581, and a conductor 161 is embedded in the insulator 287. The insulator 514 of the element layer 700[k+1] is provided over the insulator 287 and the conductor 161.

In FIG. 18 and FIG. 19A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. The other of a source and a drain of the transistor M1 is electrically connected to the conductor 161 through a contact plug, and a gate of the transistor M2 is electrically connected to the conductor 161 through another contact plug.

### <Structure Example 2 of DOSRAM>

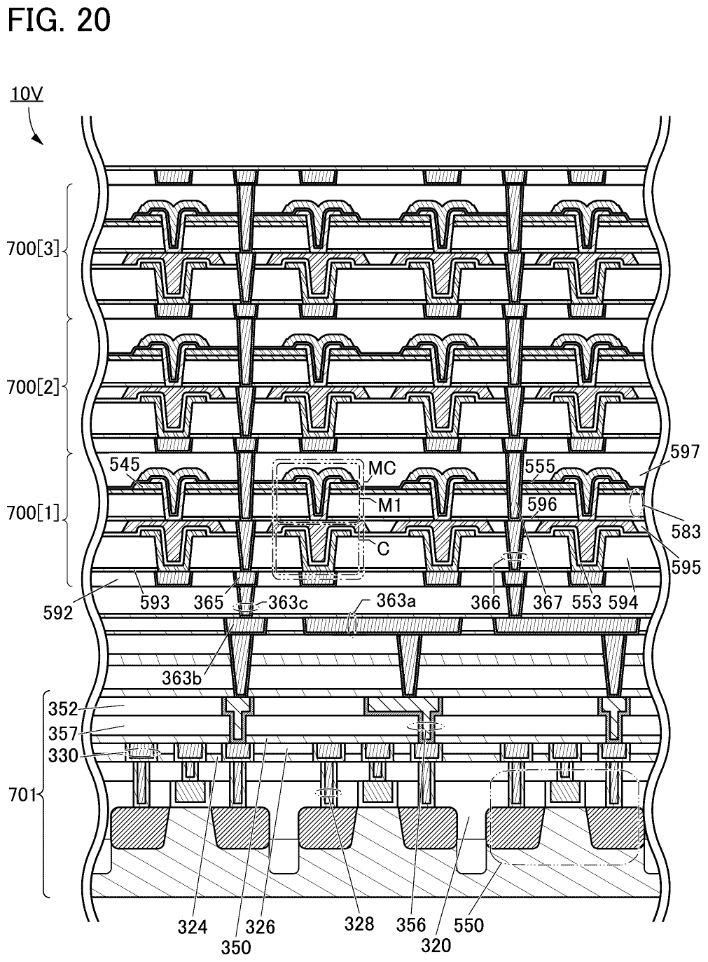

Next, FIG. 20 illustrates a cross-sectional structure example of stacked element layers including OS transistors, which can be used for the memory device of one embodiment of the present invention or the like, and is different from those in FIG. 16 to FIG. 19A and FIG. 19B. In a memory device 10V illustrated in FIG. 20, the capacitor C is provided below the transistor M1 in the memory cell MC provided in the element layer 700[1] to the element layer 700[3] illustrated in FIG. 20.

In FIG. 20, each of a plurality of element layers 700 includes a plurality of memory cells MC. In the memory cell MC illustrated in FIG. 20, the transistor M1 and the capacitor C are illustrated.

A conductor 363a, a conductor 363b, and a conductor 363c are embedded in an interlayer film between the element layer 701 and the element layer 700. In each of the plurality of element layers 700, a conductor 365 is embedded in an insulator 592 described later. Also, in each of the plurality of element layers 700, the conductor 366 is embedded in an insulator 593, an insulator 594, an insulator 553, and an insulator 595 that are described later. Furthermore, in each of the plurality of element layers 700, a conductor 367 is embedded in an insulator 596, an insulator 583, the conductor 542b, the insulator 555, and an insulator 597 that are described later. The conductor 363a, the conductor 363b, the conductor 363c, the conductor 365, the conductor 366, and the conductor 367 each function as a via hole, a contact plug, or a wiring.

Next, a structure example of the memory cell MC included in each of the plurality of element layers 700 of the memory device 10V in FIG. 20 is described.

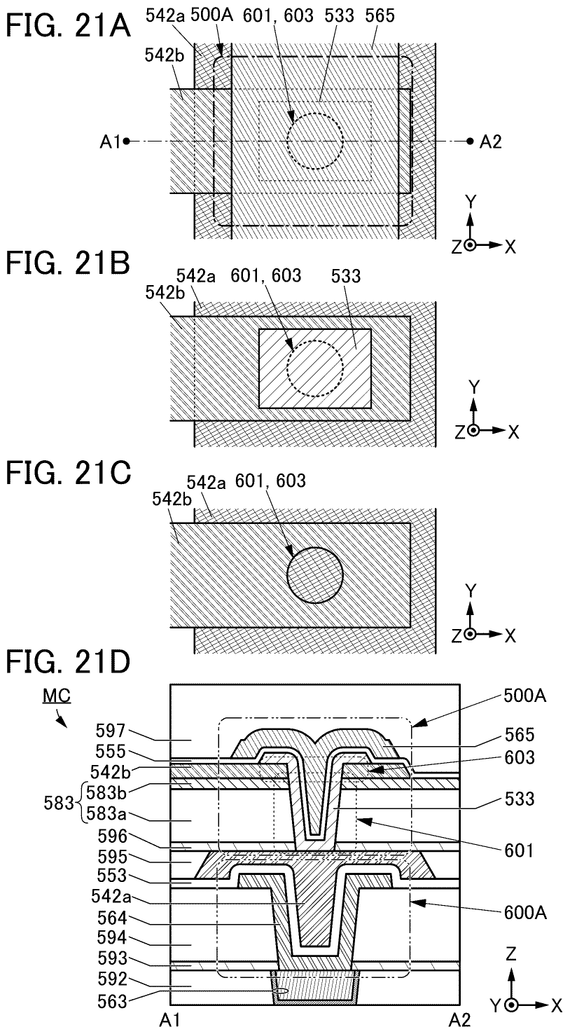

FIG. 21A is a plan view illustrating a structure example of the memory cell MC included in each of the plurality of element layers 700 of the above memory device 10V and the periphery of the memory cell MC. Note that in FIG. 21A to FIG. 21D, a transistor 500A corresponds to the transistor M1 in FIG. 20, and a capacitor 600A corresponds to the capacitor C in FIG. 20. FIG. 21D is a cross-sectional view taken along the dashed-dotted line A1-A2 in FIG. 21A. Note that in FIG. 21A, some components of the transistor M1, such as an insulator, are not illustrated. Also, in the following plan views of transistors, some components such as an insulator are not illustrated.

The capacitor 600A includes the insulator 593, the insulator 594, the insulator 553, the insulator 595, a conductor 563, a conductor 564, and the conductor 542a, for example.

The conductor 563 is embedded in the insulator 592. The conductor 563 can be, for example, the wiring PL extending in the Y direction.

The insulator 593 and the insulator 594 are formed in this order over the insulator 592 and the conductor 563, for example. An opening is provided in a region of the insulator 593 and the insulator 594 that overlaps with the conductor 563. The conductor 564 is formed on the bottom surface of the opening (over the conductor 563) and the side surface of the opening. Note that in FIG. 21D, the conductor 564 is formed also on the top surface of the insulator 594. The insulator 553 is formed over the insulator 594 and the conductor 564. The conductor 542a is formed to cover a region of the insulator 553 that overlaps with the conductor 564. The insulator 595 is formed over the conductor 542a and the insulator 553. Note that the top surface of the insulator 595 and the top surface of the conductor 542a are preferably substantially level with each other. Therefore, the insulator 595 and the conductor 542a are preferably planarized by planarization treatment using a chemical mechanical polishing (CMP) method or the like, for example.

The conductor 564 corresponds to one of a pair of terminals of the capacitor 600A, for example. The conductor 542a corresponds to the other of the pair of terminals of the capacitor 600A, for example.

The insulator 553 functions as a dielectric sandwiched between a pair of terminals of the capacitor 600A, for example.

The transistor 500A is provided above the conductor 542a and the insulator 595 of the capacitor 600A.

In the transistor 500A, the channel length direction is not substantially parallel to the substrate 311 but along the side surface of a later-described opening provided in the insulator 583.

The transistor 500A includes the conductor 542a functioning as one of the source electrode and the drain electrode, the conductor 542b functioning as the other of the source electrode and the drain electrode, a metal oxide 533, the insulator 555, and a conductor 565 functioning as a gate electrode, for example. FIG. 21A illustrates an example in which the conductor 542b extends in the direction perpendicular to the conductor 542a and the conductor 565. Note that as described above, the conductor 542a functions also as the other of the pair of electrodes of the capacitor 600A.

For the metal oxide 533, for example, the material that can be used for the oxide 530 included in the transistor 500 described in the above embodiment can be used.

In FIG. 21A and FIG. 21D of this embodiment, the direction in which the conductor 542b extends is referred to as the X direction. The direction perpendicular to the X direction and parallel to the top surface of the conductor 563, for example, is referred to as the Y direction, and the direction perpendicular to the top surface of the conductor 563 is referred to as the Z direction.

The definition of the X direction, the Y direction, and the Z direction applies to the following drawings in some cases. The X direction, the Y direction, and the Z direction can be perpendicular to each other. In the description of a plan view in this specification and the like, the X direction may be referred to as the right side or the left side and the Y direction may be referred to as the upper side or the lower side. The right side may be rephrased as the X direction, the left side may be referred to as the −X direction, the upper side may be referred to as the Y direction, and the lower side may be referred to as the −Y direction in some cases.

The conductor 542a functions as one of the source electrode and the drain electrode of the transistor 500A. The conductor 542b functions as the other of the source electrode and the drain electrode of the transistor 500A. The insulator 555 functions as a gate insulating layer of the transistor 500A. The conductor 565 functions as the gate electrode of the transistor 500A.

In the metal oxide 533 between the source electrode and the drain electrode, the whole region overlapping with the gate electrode with the gate insulating layer therebetween functions as the channel formation region. The metal oxide 533 including a region functioning as the channel formation region is referred to as a semiconductor layer in some cases. In the metal oxide 533, a region in contact with the source electrode functions as a source region, and a region in contact with the drain electrode functions as a drain region.

The insulator 596 is provided over the insulator 595 and the conductor 542a. The insulator 596 can function as an interlayer insulating layer. The interlayer insulating layer here can be a barrier insulating film that inhibits diffusion of impurities such as water and hydrogen (e.g., one or both of a hydrogen atom and a hydrogen molecule).

The insulator 583 (an insulator 583a and an insulator 583b) is provided over the insulator 596, and the conductor 542b is provided over the insulator 583. The insulator 583 can function as an interlayer insulating layer. The interlayer insulating layer here can be an interlayer film for separation of the source electrode and the gate electrode in 500A.

An oxide or an oxynitride is preferably used as the insulator 583a, for example. The insulator 583a is preferably formed using a film from which oxygen is released by heating. As the insulator 583a, silicon oxide or silicon oxynitride can be suitably used, for example. Oxygen release from the insulator 583a enables oxygen supply from the insulator 583a to the metal oxide 533. When oxygen is supplied from the insulator 583a to the metal oxide 533, in particular, the channel formation region of the metal oxide 533, oxygen vacancies (Vo), VoH, and hydrogen in the metal oxide 533 can be reduced. Consequently, the transistor 500A with favorable electrical characteristics and high reliability can be obtained.

The insulator 583b preferably includes a region containing more nitrogen than the insulator 583a, for example. For example, silicon nitride or silicon nitride oxide can be suitably used for the insulator 583b. When silicon nitride or silicon nitride oxide is used for the insulator 583b, the insulator 583b can serve as a blocking layer that inhibits release of oxygen from the insulator 583a.

The insulator 596 and the insulator 583 each include an opening 601 reaching the conductor 542a. The conductor 542b includes an opening 603 reaching the opening 601. That is, the opening 603 includes a region overlapping with the opening 601.

FIG. 21A illustrates, as the components of the transistor 500A, the conductor 542a, the conductor 542b, the metal oxide 533, the conductor 565, the opening 601 and the opening 603. FIG. 21B illustrates a structure example in which the conductor 565 is omitted from the components illustrated in FIG. 21A. In other words, FIG. 21B illustrates the conductor 542a, the conductor 542b, the metal oxide 533, the opening 601, and the opening 603. FIG. 21C illustrates a structure example in which the metal oxide 533 is further omitted from the components illustrated in FIG. 21B. In other words, FIG. 21C illustrates the conductor 542a, the conductor 542b, the opening 601, and the opening 603.

As illustrated in FIG. 21C and FIG. 21D, the conductor 542b includes the opening 603 in a region overlapping with the conductor 542a. As illustrated in FIG. 21C, the conductor 542b can be formed to entirely surround the periphery of the opening 601 in a plan view. It is preferable that the conductor 542b not be provided in the opening 601. In other words, it is preferable that the conductor 542b be not in contact with the side surface of the insulator 583 on the opening 601 side.

FIG. 21A to FIG. 21C each illustrate an example in which the opening 601 and the opening 603 are each circular in a plan view. In the case where the planar shapes of the opening 601 and the opening 603 are circular, high processing accuracy in forming each of the opening 601 and the opening 603 is possible and the opening 601 and the opening 603 having minute sizes can be formed. Note that in this specification and the like, a circular shape is not necessarily a perfect circular shape. For example, the planar shapes of the opening 601 and the opening 603 may be elliptical or shapes including a curve. Alternatively, the planar shapes of the opening 601 and the opening 603 may be polygonal.

FIG. 21D illustrates an example in which the end portion of the conductor 542b on the opening 603 side is aligned with or substantially aligned with the end portion of the insulator 583 on the opening 601 side. In other words, the planar shape of the opening 603 is the same or substantially the same as the planar shape of the opening 601. Note that in this specification and the like, the end portion of the conductor 542b on the opening 603 side refers to the end portion of the bottom surface of the conductor 542b on the opening 603 side. The bottom surface of the conductor 542b refers to the surface on the insulator 583 side. The end portion of the insulator 583 on the opening 601 side refers to the end portion of the top surface of the insulator 583 on the opening 601 side. The top surface of the insulator 583 refers to the surface on the conductor 542b side. The planar shape of the opening 603 refers to the planar shape of the end portion of the bottom surface of the conductor 542b on the opening 603 side. The planar shape of the opening 601 refers to the planar shape of the end portion of the top surface of the insulator 583 on the opening 601 side.

In the case where end portions are aligned or substantially aligned with each other, the end portions can also be said to match or substantially match. In the case where end portions match or substantially match and the case where planar shapes are the same or substantially the same, it can be said that outlines of stacked layers at least partly overlap with each other in a plan view. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions substantially match” or the expression “planar shapes are substantially the same”.

The opening 601 can be formed using a resist mask used for the formation of the opening 603, for example. Specifically, first, the insulator 596 is formed over the conductor 542a and the insulator 595, the insulator 583 is formed over the insulator 596, a conductive film to be the conductor 542b is formed over the insulator 583, and a resist mask is formed over the conductive film. Then, the opening 603 is formed in the conductive film using the resist mask and then the opening 601 is formed in the insulator 596 and the insulator 583 using the resist mask, whereby the end portion of the opening 601 and the end portion of the opening 603 can be aligned or substantially aligned with each other. With such a structure, the process can be simplified.

The metal oxide 533 is provided to include a region positioned inside the opening 601 and the opening 603 to cover the opening 601 and the opening 603. The metal oxide 533 has a shape along the top surface and the side surface of the conductor 542b, the side surface of the insulator 583, the side surface of the insulator 596 and the top surface of the conductor 542a. The metal oxide 533 includes, for example, a region in contact with the top surface and the side surface of the conductor 542b, the side surface of the insulator 583, and the top surface of the conductor 542a.

The metal oxide 533 preferably covers the end portion of the conductor 542b on the opening 603 side. For example, FIG. 21D illustrates a structure in which the end portion of the metal oxide 533 is positioned over the conductor 542b. The end portion of the metal oxide 533 can also be said to be in contact with the top surface of the conductor 542b.

Although the metal oxide 533 has a single-layer structure in FIG. 21D, for example, one embodiment of the present invention is not limited thereto. The metal oxide 533 may have a stacked-layer structure of two or more layers.

The insulator 555 functioning as the gate insulating layer of the transistor 500A is provided to cover the opening 601 and the opening 603 and include a region positioned in the opening 601 and the opening 603. The insulator 555 is provided over the metal oxide 533, over the conductor 542b, and over the insulator 583. The insulator 555 can include a region in contact with the top surface and the side surface of the metal oxide 533, the top surface and the side surface of the conductor 542b, the top surface of the insulator 583, and the top surface of the insulator 596. The insulator 555 has a shape along the top surface of the insulator 596, the top surface of the insulator 583, the top surface and the side surface of the conductor 542b, and the top surface and the side surface of the metal oxide 533.

The conductor 565 functioning as the gate electrode of the transistor 500A can be provided over the insulator 555 and can include a region in contact with the top surface of the insulator 555. The conductor 565 includes a region overlapping with the metal oxide 533 with the insulator 555 therebetween. The conductor 565 has a shape along the shape of the top surface of the insulator 555.

For example, as illustrated in FIG. 21D, the conductor 565 includes a region overlapping with the metal oxide 533 with the insulator 555 therebetween in the opening 601 and the opening 603. In the example illustrated in FIG. 21D, the conductor 565 includes a region overlapping with the conductor 542a and the conductor 542b with the insulator 555 and the metal oxide 533 therebetween. The conductor 565 covers the entire metal oxide 533. With such a structure, a gate electric field can be applied to the entire metal oxide 533, which allows the transistor 500A to have better electrical characteristics, for example, the on-state current of the transistor can be increased.

The transistor 500A is what is called a top-gate transistor including a gate electrode above the metal oxide 533. Furthermore, since the bottom surface of the metal oxide 533 includes a region in contact with the source electrode and the drain electrode, the transistor 500A can be referred to as a TGBC (Top Gate Bottom Contact) transistor.

The transistor 500A can also be used as a transistor included in a circuit different from the memory cell MC, for example.

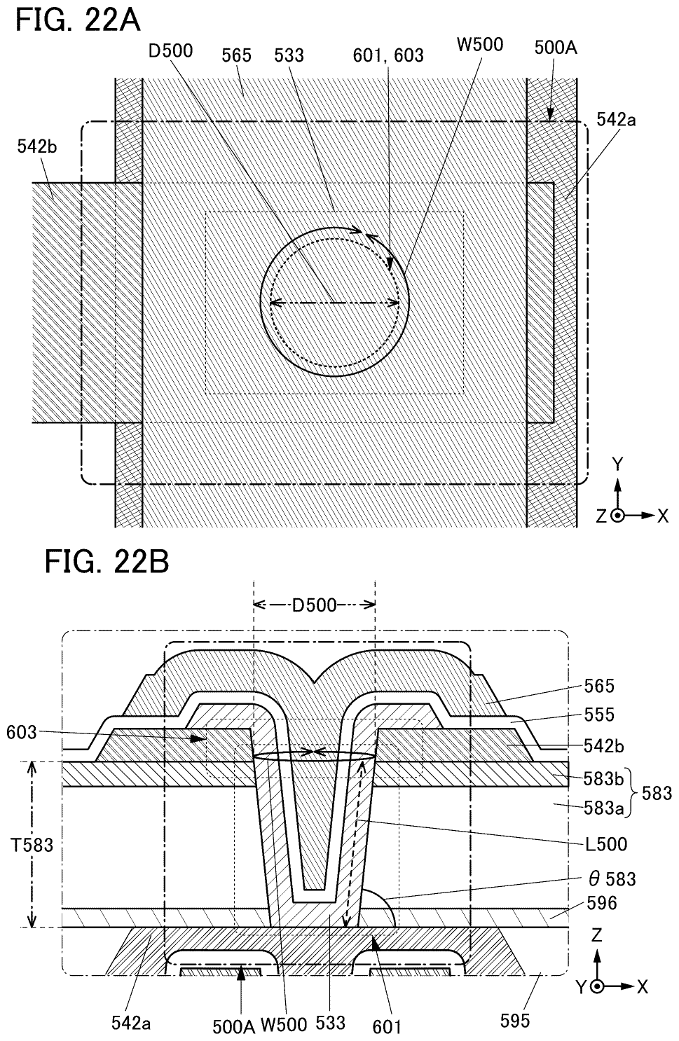

Here, the channel length and channel width of the transistor 500A are described with reference to FIG. 22A and FIG. 22B. FIG. 22A is an enlarged view of the plan view of FIG. 21A illustrating the structure example of the transistor 500A and the vicinity thereof. FIG. 22B is an enlarged view of the cross-sectional view of FIG. 21D illustrating the structure example of the transistor 500A and the vicinity thereof.

In the metal oxide 533, a region in contact with the conductor 542a functions as one of the source region and the drain region, a region in contact with the conductor 542b functions as the other of the source region and the drain region, and a region between the source region and the drain region functions as the channel formation region.

The channel length of the transistor 500A is a distance between the source region and the drain region. In FIG. 22B, a channel length L500 of the transistor 500A is indicated by a dashed double-headed arrow. In the cross-sectional view, the channel length L500 is a distance between the end portion of the region where the metal oxide 533 is in contact with the conductor 542a and the end portion of the region where the metal oxide 533 is in contact with the conductor 542b.

Here, the channel length L500 of the transistor 500A corresponds to the length of the side surface of the insulator 583 on the opening 601 side when seen from the XZ plane. In other words, the channel length L500 is determined depending on a thickness T583 of the insulator 583 and an angle θ583 formed by the side surface of the insulator 583 on the opening 601 side and the formation surface of the insulator 583 (here, the top surface of the conductor 542a), and is not affected by the performance of a light-exposure apparatus used for manufacturing the transistor. Thus, the channel length L500 can be a value smaller than that of the resolution limit of the light-exposure apparatus, which enables the transistor to have a minute size. For example, the channel length L500 is preferably larger than or equal to 0.010 μm and smaller than 3.0 μm, further preferably larger than or equal to 0.050 μm and smaller than 3.0 μm, still further preferably larger than or equal to 0.10 μm and smaller than 3.0 μm, yet still further preferably larger than or equal to 0.15 μm and smaller than 3.0 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. In FIG. 22B, the thickness T583 of the insulator 583 is indicated by a dashed-dotted double-headed arrow.

When the transistor 500A is used as a transistor included in the memory cell MC, the memory cell MC can be miniaturized. Accordingly, a memory device with increased memory density can be obtained. Furthermore, when the channel length L500 is reduced, the on-state current of the transistor 500A can be increased, so that the memory cell MC can be driven at high speed.

The channel length L500 can be controlled by adjustment of the thickness T583 of the insulator 596 and the insulator 583 and the angle θ583.

The thickness T583 of the insulator 596 and the insulator 583 is preferably greater than or equal to 0.010 μm and less than 3.0 μm, further preferably greater than or equal to 0.050 μm and less than 3.0 μm, further preferably greater than or equal to 0.10 μm and less than 3.0 μm, still further preferably greater than or equal to 0.15 μm and less than 3.0 μm, yet still further preferably greater than or equal to 0.20 μm and less than 3.0 μm, yet still further preferably greater than or equal to 0.20 μm and less than 2.5 μm, yet still further preferably greater than or equal to 0.20 μm and less than 2.0 μm, yet still further preferably greater than or equal to 0.20 μm and less than 1.5 μm, yet still further preferably greater than or equal to 0.30 μm and less than 1.5 μm, yet still further preferably greater than or equal to 0.30 μm and less than or equal to 1.2 μm, yet still further preferably greater than or equal to 0.40 μm and less than or equal to 1.2 μm, yet still further preferably greater than or equal to 0.40 μm and less than or equal to 1.0 μm, yet still further preferably greater than or equal to 0.50 μm and less than or equal to 1.0 μm.

The side surfaces of the insulator 596 and the insulator 583 on the opening 601 side preferably each have a tapered shape. The angle θ583 formed by the side surfaces of the insulator 596 and the insulator 583 on the opening 601 side and the formation surface of the insulator 596 (here, the top surface of the conductor 542a) is preferably less than or equal to 90°. By reducing the angle θ583, the coverage with a layer provided over the insulator 583 (e.g., the metal oxide 533) can be improved. However, reducing the angle θ583 might reduce the contact area between the metal oxide 533 and the conductor 542a to increase the contact resistance between the metal oxide 533 and the conductor 542a. The angle θ583 is preferably greater than or equal to 45° and less than or equal to 90°, further preferably greater than or equal to 50° and less than or equal to 90°, further preferably greater than or equal to 55° and less than or equal to 90°, further preferably greater than or equal to 60° and less than or equal to 90°, further preferably greater than or equal to 60° and less than or equal to 85°, still further preferably greater than or equal to 65° and less than or equal to 85°, yet further preferably greater than or equal to 65° and less than or equal to 80°, yet still further preferably greater than or equal to 70° and less than or equal to 80°. When the angle θ583 is within the above range, the coverage with the layer formed over the conductor 542a and the insulator 583 (e.g., the metal oxide 533) can be improved, which can inhibit defects such as step disconnection or a void from being generated in the layer. In addition, the contact resistance between the metal oxide 533 and the conductor 542a can be reduced.

In this specification and the like, step disconnection refers to a phenomenon in which a layer, a film, or an electrode is split because of the shape of the formation surface (e.g., a step).

Although FIG. 22B illustrates the structure in which the side surfaces of the insulator 596 and the insulator 583 on the opening 601 side are linear in the cross-sectional view, one embodiment of the present invention is not limited thereto. In the cross-sectional view, the side surfaces of the insulator 596 and the insulator 583 on the opening 601 side may be curved, or the side surfaces may include both a linear region and a curved region.

The channel width of the transistor 500A is a width of the source region or a width of the drain region in the direction orthogonal to the channel length direction. In other words, the channel width is the width of the region where the metal oxide 533 is in contact with the conductor 542a or the width of the region where the metal oxide 533 is in contact with the conductor 542b in the direction orthogonal to the channel length direction. Here, the channel width of the transistor 500A is described as the width of the region where the metal oxide 533 and the conductor 542b are in contact with each other in the direction orthogonal to the channel length direction. In FIG. 22A and FIG. 22B, a channel width W500 of the transistor 500A is indicated by a solid double-headed arrow. In the plan view, the channel width W500 is the length of the end portion of the bottom surface of the conductor 542b on the opening 603 side.

The channel width W500 is determined by the planar shape of the opening 603. In FIG. 22A and FIG. 22B, the width D500 of the opening 603 is indicated by a dashed-two dotted double-headed arrow. In the plan view, the width D500 refers to the short side of the smallest rectangle that is circumscribed around the opening 603. In the case where the opening 603 is formed by a photolithography method, the width D500 of the opening 603 is larger than or equal to the resolution limit of a light-exposure apparatus. For example, the width D500 is preferably larger than or equal to 0.20 μm and smaller than 5.0 μm, further preferably larger than or equal to 0.20 μm and smaller than 4.5 μm, still further preferably larger than or equal to 0.20 μm and smaller than 4.0 μm, yet still further preferably larger than or equal to 0.20 μm and smaller than 3.5 μm, yet still further preferably larger than or equal to 0.20 μm and smaller than 3.0 μm, yet still further preferably larger than or equal to 0.20 μm and smaller than 2.5 μm, yet still further preferably larger than or equal to 0.20 μm and smaller than 2.0 μm, yet still further preferably larger than or equal to 0.20 μm and smaller than 1.5 μm, yet still further preferably larger than or equal to 0.30 μm and smaller than 1.5 μm, yet still further preferably larger than or equal to 0.30 μm and smaller than or equal to 1.2 μm, yet still further preferably larger than or equal to 0.40 μm and smaller than or equal to 1.2 μm, yet still further preferably larger than or equal to 0.40 μm and smaller than or equal to 1.0 μm, yet still further preferably larger than or equal to 0.50 μm and smaller than or equal to 1.0 μm. Note that when the planar shape of the opening 603 is circular, the width D500 corresponds to the diameter of the opening 603, and the channel width W500 can be equal to the length of the periphery of the opening 603 in a plan view and calculated to be “D500×π”.

Since the size of the transistor 500A is small, by using the transistor 500A for the element layer 700, a semiconductor device with high memory density can be provided. Since the operation speed of the transistor 500A is high, by using the transistor 500A for a semiconductor device, a semiconductor device with high driving speed can be provided. Since the electrical characteristics of the transistor 500A are stable, by using the transistor 500A for a semiconductor device, a semiconductor device with high reliability can be provided. Since the amount of the off-state current of the transistor 500A is small, by using the transistor 500A for a semiconductor device, a semiconductor device with low power consumption can be provided.

This embodiment can be implemented in combination with the other embodiments described in this specification as appropriate.

### Embodiment 4

In this embodiment, a transistor whose channel formation region includes an oxide semiconductor (OS transistor) is described. In the description of the OS transistor, comparison with a transistor whose channel formation region includes silicon (also referred to as a Si transistor) is also briefly described.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to a gate electrode, a channel exists and current flows through the transistor). Accordingly, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can inhibit the short-channel effect. In other words, the OS transistor is a transistor where the short-channel effect does not appear or the short-channel effect hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor, and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, a difference in energy of the conduction band minimum between the channel formation region and the source region or the drain region might decrease to higher than or equal to 0.1 eV and lower than or equal to 0.2 eV. Accordingly, the OS transistor can be regarded as having an n⁺/n⁻/n⁺accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor with the above structure can have favorable electrical characteristics even when a semiconductor device is miniaturized or highly integrated. For example, the OS transistor can have favorable electrical characteristics even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm due to appearance of the short-channel effect. Thus, an OS transistor can be used as a transistor with a short channel length more suitably than a Si transistor. Note that the gate length refers to the length of a gate electrode in the direction in which carriers move inside a channel formation region during operation of a transistor, and corresponds to the width of a bottom surface of the gate electrode in a plan view of the transistor.

Miniaturization of an OS transistor can improve the high frequency characteristics of the transistor. Specifically, the cutoff frequency of the transistor can be increased. When the gate length of the OS transistor is within any of the above ranges, the cutoff frequency of the transistor can be greater than or equal to 50 GHz, preferably greater than or equal to 100 GHz, further preferably greater than or equal to 150 GHz at room temperature, for example.

As described above, the OS transistor has advantageous effects over the Si transistor, such as lower off-state current and the capability of being manufactured with a shorter channel length.

The configuration, structure, method, and the like described in this embodiment can be used in combination as appropriate with the configurations, structures, methods, and the like described in the other embodiments and the like.

### Embodiment 5

This embodiment will describe an electronic component, an electronic device, a large computer, space equipment, and a data center (also referred to as a DC) that can use the semiconductor device described in the above embodiment. An electronic component, an electronic device, a large computer, space equipment, and a data center each using the semiconductor device of one embodiment of the present invention are effective in achieving high performance, e.g., reducing power consumption.

### [Electronic Component]

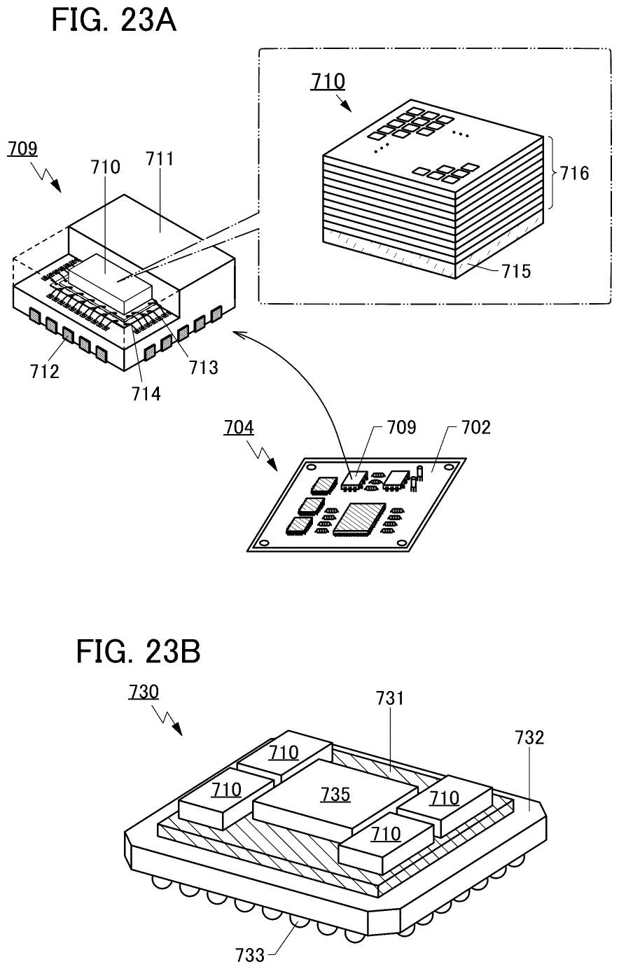

FIG. 23A is a perspective view of a substrate (a circuit board 704) on which an electronic component 709 is mounted. The electronic component 709 illustrated in FIG. 23A includes a semiconductor device 710 in a mold 711. Some components are omitted in FIG. 23A to show the inside of the electronic component 709. The electronic component 709 includes a land 712 outside the mold 711. The land 712 is electrically connected to an electrode pad 713, and the electrode pad 713 is electrically connected to the semiconductor device 710 through a wire 714. The electronic component 709 is mounted on a printed circuit board 702, for example. A plurality of such electronic components are combined and electrically connected to each other on the printed circuit board 702, which forms the circuit board 704.

The semiconductor device 710 includes a driver circuit layer 715 and an element layer 716. The element layer 716 has a structure in which a plurality of memory cell arrays are stacked. A stacked-layer structure of the driver circuit layer 715 and the element layer 716 can be a monolithic stacked-layer structure. In the monolithic stacked-layer structure, layers can be connected without using a through electrode technique such as a TSV (Through Silicon Via) and a bonding technique such as Cu—Cu direct bonding. The monolithic stacked-layer structure of the driver circuit layer 715 and the element layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where a through electrode technique such as a TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the element layer 716 be formed using OS transistors and the plurality of memory cell arrays be monolithically stacked. The monolithic stacked-layer structure of a plurality of memory cell arrays can improve one or both of the bandwidth of the memory and the access latency of the memory. Note that a bandwidth refers to a data transfer volume per unit time, and access latency refers to time from access to start of data transmission. In the case where the element layer 716 is formed using Si transistors, it is difficult to obtain the monolithic stacked-layer structure as compared with the case where the element layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Note that examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 23B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. In some cases, a through electrode is provided in the interposer 731, and the through electrode is used to electrically connect an integrated circuit and the package substrate 732. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like each using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected using a silicon interposer, a TSV, and the like, a space for the width of the terminal pitch and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using a TSV and monolithically stacked memory cell arrays may be employed.

In addition, a heat sink (radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor device 710 and the semiconductor device 735 are preferably equal to each other.

To mount the electronic component 730 on another substrate, an electrode 733 may be provided on the bottom portion of the package substrate 732. FIG. 23B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

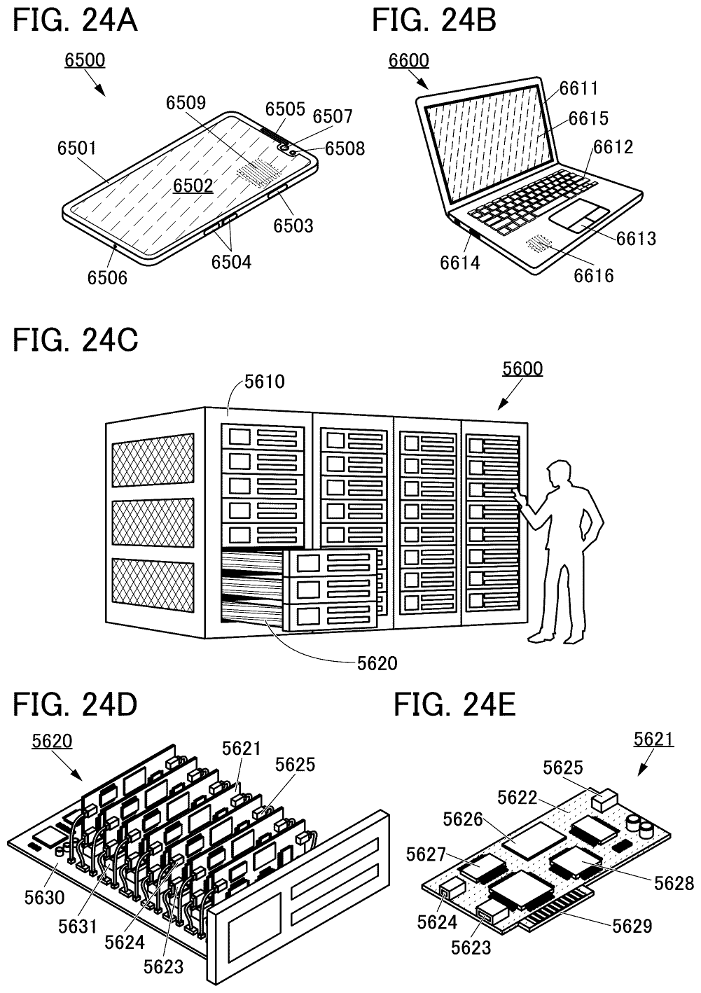

FIG. 24A is a perspective view of an electronic device 6500. The electronic device 6500 illustrated in FIG. 24A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that the control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 24B is an information terminal that can be used as a notebook computer. The electronic device 6600 includes a housing 6611, a keyboard 6612, a pointing device 6613, an external connection port 6614, a display portion 6615, a control device 6616, and the like. Note that the control device 6616 includes one or more selected from a CPU, a GPU, and a memory device, for example. The semiconductor device of one embodiment of the present invention can be used for the display portion 6615, the control device 6616, and the like. Note that the semiconductor device of one embodiment of the present invention is suitably used for the control device 6509 and the control device 6616, in which case power consumption can be reduced.

### [Large Computer]

Next, a perspective view of a large computer 5600 is illustrated in FIG. 24C. In the large computer 5600 illustrated in FIG. 24C, a plurality of rack mount computers 5620 are stored in a rack 5610. Note that the large computer 5600 may be referred to as a supercomputer.

The computer 5620 can have a structure in a perspective view illustrated in FIG. 24D, for example. In FIG. 24D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 24E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 24E illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

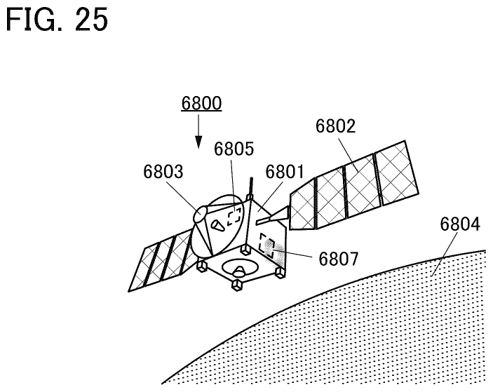

FIG. 25 illustrates an artificial satellite 6800 as an example of space equipment. The artificial satellite 6800 includes a body 6801, a solar panel 6802, an antenna 6803, a secondary battery 6805, and a control device 6807. Note that in FIG. 25, a planet 6804 in outer space is illustrated as an example. Note that outer space refers to, for example, space at an altitude greater than or equal to 100 km, and outer space described in this specification may also include the thermosphere, mesosphere, and stratosphere.

Although not illustrated in FIG. 25, the secondary battery 6805 may be provided with a battery management system (also referred to as a BMS) or a battery control circuit. An OS transistor is suitably used in the battery management system or the battery control circuit because low power consumption and high reliability even in outer space are achieved.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in a situation where the solar panel is not irradiated with sunlight or in a situation where the amount of sunlight with which the solar panel is irradiated is small, the amount of generated electric power is small. Accordingly, electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has excellent effects of achieving wide memory bandwidth and being highly resistant to radiation as compared with the Si transistor.

### [Data Center]

The semiconductor device of one embodiment of the present invention can be suitably used for a storage system in a data center, for example. Long-term management of data, such as guarantee of data immutability, is required for the data center. The long-term management of data needs an increase in building size for, for example, setting a storage and a server for storing an enormous amount of data, ensuring stable power supply for data retention, and ensuring cooling equipment for data retention.

With the use of the semiconductor device of one embodiment of the present invention for the storage system used in the data center, electric power required for data retention can be reduced and a semiconductor device retaining data can be downsized. Thus, downsizing of the storage system, downsizing of the power supply for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

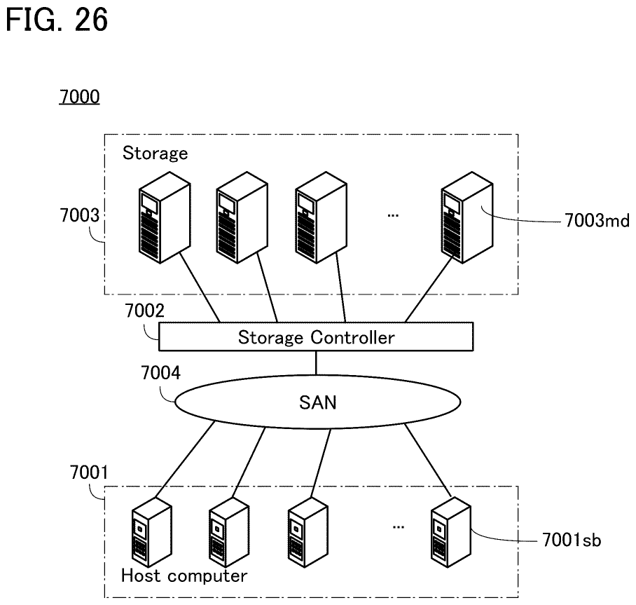

FIG. 26 illustrates a storage system that can be used in a data center. A storage system 7000 illustrated in FIG. 26 includes a plurality of servers 7001sb as a host 7001 (indicated as “Host Computer” in the diagram). The storage system 7000 also includes a plurality of memory devices 7003md as a storage 7003 (indicated as “Storage” in the diagram). In the illustrated mode, the host 7001 and the storage 7003 are connected through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is considerably longer than the data access speed of a DRAM that can be used as a cache memory in the storage. In the storage system, in order to solve the problem of low access speed of the storage 7003, a cache memory is normally provided in the storage to shorten the time for data storage and output.

The cache memories are used in the storage control circuit 7002 and the storage 7003. Data transmitted between the host 7001 and the storage 7003 are stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

Note that the use of the semiconductor device of one embodiment of the present invention for one or more selected from an electronic component, an electronic device, a large computer, space equipment, and a data center is expected to produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. The semiconductor device of one embodiment of the present invention can be effectively used as one of the global warming countermeasures because of its low power consumption.

The configuration, structure, method, and the like described in this embodiment can be used in combination as appropriate with the configurations, structures, methods, and the like described in the other embodiments and the like.

<Supplementary Notes on Description in this Specification and the Like>

The following are notes on the description of the above embodiments and the structures in the embodiments.

One embodiment of the present invention can be constituted by combining, as appropriate, the structure described in each embodiment with the structures described in the other embodiments. In the case where a plurality of structure examples are described in one embodiment, the structure examples can be combined as appropriate.

Note that content (or may be part of the content) described in one embodiment can be applied to, combined with, or replaced with another content (or may be part of the content) described in the embodiment and/or content (or may be part of the content) described in another embodiment or other embodiments.

Note that in each embodiment, content described in the embodiment is content described using a variety of diagrams or content described with text disclosed in the specification.

Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.

In this specification and the like, components are classified on the basis of the functions, and shown as blocks independent of each other in block diagrams. However, in an actual circuit or the like, it is difficult to separate components on the basis of the functions, and there is such a case where one circuit is associated with a plurality of functions or a case where a plurality of circuits are associated with one function. Therefore, blocks in the block diagrams are not limited by the components described in this specification, and the description can be changed appropriately depending on the situation.

In the drawings, the size, the layer thickness, or the region is shown with given magnitude for description convenience. Therefore, they are not limited to the illustrated scale. Note that the drawings are schematically shown for clarity, and embodiments of the present invention are not limited to shapes, values or the like shown in the drawings. For example, variations in signal, voltage, or current due to noise, variations in signal, voltage, or current due to difference in timing, or the like can be included.

In this specification and the like, expressions “one of a source and a drain” (or a first electrode or a first terminal) and “the other of the source and the drain” (or a second electrode or a second terminal) are used in the description of the connection relation of a transistor. This is because the source and the drain of the transistor change depending on the structure, operating conditions, or the like of the transistor. Note that the source or the drain of the transistor can also be referred to as a source (drain) terminal, a source (drain) electrode, or the like as appropriate depending on the situation.

In this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.

In this specification and the like, “voltage” and “potential” can be interchanged with each other as appropriate. Voltage refers to a potential difference from a reference potential, and when the reference potential is a ground voltage, for example, voltage can be replaced with potential. The ground potential does not necessarily mean 0 V. Note that potentials are relative values, and a potential applied to a wiring or the like is sometimes changed depending on the reference potential.

Note that in this specification and the like, the terms such as “film” and “layer” can be interchanged with each other depending on the case or according to circumstances. For example, the term “conductive layer” can be replaced with the term “conductive film” in some cases. As another example, the term “insulating film” can be replaced with the term “insulating layer” in some cases.

In this specification and the like, a switch has a function of controlling whether current flows or not by being in a conducting state (on state) or a non-conducting state (off state). Alternatively, a switch has a function of selecting and changing a current path.

In this specification and the like, channel length of a planar transistor refers to, for example, the distance between a source and a drain in a region where a semiconductor (or a portion where current flows in a semiconductor when a transistor is in an on state) and a gate overlap with each other or a region where a channel is formed in a top view of the transistor.

In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.

In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.

In this specification and the like, the expression “A and B are connected” means the case where A and B are electrically connected. Here, the expression “A and B are electrically connected” means connection that enables electrical signal transmission between A and B in the case where an object (which refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

### REFERENCE NUMERALS

10: memory device, 20: element layer, 21: precharge circuit, 22: sense amplifier, 23: reading circuit, 30: element layer, 31: cell array, 32: memory cell, 33: transistor, 34: capacitor, 40: control circuit, 50: input/output circuit

1. A semiconductor device comprising:
an arithmetic device;
a bus wiring; and
a memory device,
wherein the memory device comprises a first element layer comprising a plurality of reading circuits and a second element layer comprising a plurality of cell arrays,
wherein the reading circuits each comprise a sense amplifier,
wherein the cell arrays each comprise a memory cell,
wherein the second element layer is positioned over and overlap with the first element layer,
wherein the memory cell and the sense amplifier are electrically connected to each other through a bit line,
wherein the memory device is electrically connected to the arithmetic device through the bus wiring, and
wherein data retained in one of the plurality of cell arrays is output to the bus wiring through one of the plurality of reading circuits.

2. The semiconductor device according to claim 1,
wherein the data output to the bus wiring is output with a bit width that is a multiple of 8 bits.

3. The semiconductor device according to claim 1,
wherein the first element layer comprises an input/output circuit, and
wherein the input/output circuit comprises a plurality of interface circuits.

4. The semiconductor device according to claim 1,
wherein the reading circuits each comprise a precharge circuit.

5. The semiconductor device according to claim 1,
wherein the first element layer comprises a first transistor in which a first semiconductor layer comprising a channel formation region comprises silicon, and
wherein the second element layer comprises a second transistor in which a second semiconductor layer comprising a channel formation region comprises an oxide semiconductor.

6. The semiconductor device according to claim 5,
wherein the oxide semiconductor comprises In, Ga, and Zn.

7. The semiconductor device according to claim 5,
wherein the memory cell comprises a capacitor and the second transistor,
wherein the capacitor comprises a first conductor, a second conductor, a first insulator, and a second insulator,
wherein the second transistor comprises the second conductor, a third conductor, a fourth conductor, a third insulator, a fourth insulator, and the second semiconductor layer,
wherein the first insulator comprises a first opening,
wherein the first conductor is positioned on a side surface and a bottom surface of the first opening and a top surface of the first insulator,
wherein the second insulator is positioned on the top surface of the first insulator and a top surface and a side surface of the first conductor,
wherein the second conductor is positioned in a region of a top surface and a side surface of the second insulator that overlaps with the first conductor,
wherein the third insulator is positioned on a top surface of the second conductor,
wherein the third conductor is positioned on a top surface of the third insulator,
wherein the third insulator and the third conductor comprise a second opening,
wherein the second semiconductor layer is positioned on a side surface of the second opening, the top surface of the second conductor, and a top surface and a side surface of the third conductor,
wherein the fourth insulator is positioned on a top surface and a side surface of the second semiconductor layer and the top surface of the third conductor, and
wherein the fourth conductor is positioned in a region of a top surface and a side surface of the fourth insulator that overlaps with the second semiconductor layer.
